(19) United States
(12) Patent Application Publication
(10) Pub. No.: US 2016/0020327 A1
(43) Pub. Date: Jan. 21, 2016

(54) SEMICONDUCTOR DEVICE, DISPLAY UNIT, AND ELECTRONIC APPARATUS

(71) Applicant: Sony Corporation, Tokyo (JP)

(72) Inventors: Shinya Yamakawa, Kanagawa (JP); Akiko Honjo, Kanagawa (JP)

(21) Appl. No.: 14/739,594

(22) Filed: Jun. 15, 2015

(30) Foreign Application Priority Data
Jul. 16, 2014 (JP) 2014-145810

(51) Int. Cl. H01L 29/786; H01L 29/417

(52) U.S. Cl. CPC H01L 29/7869; H01L 29/41733

(57) ABSTRACT

A semiconductor device includes: an oxide semiconductor film; a gate insulating film; and a gate electrode, the oxide semiconductor film, the gate insulating film, and the gate electrode being provided in this order on a substrate, in which a thick-film section is provided in one or both of end portions of the gate insulating film, the thick-film section having a larger thickness than a thickness of a portion other than the thick-film section of the gate insulating film.

### CROSS REFERENCE TO RELATED APPLICATIONS

This application claims the benefit of Japanese Priority Patent Application JP 2014-145810 filed Jul. 16, 2014, the entire contents of each which is incorporated herein by reference.

### BACKGROUND

The present technology relates to a semiconductor device using an oxide semiconductor film, and a display unit and an electronic apparatus each of which includes the semiconductor device.

It has been known that an oxide semiconductor such as zinc oxide (ZnO) and an oxide containing oxygen and indium (In) has superior electric properties. In recent years, application of such a oxide semiconductor to TFTs (Thin Film Transistors) has been studied, and application of the oxide semiconductor to a driving device and a high-voltage device of an active matrix display is expected (for example, refer to Japanese Unexamined Patent Application Publication Nos. 2009-99847, 2013-207193, and 2012-256838).

The oxide semiconductor has a wider band gap than silicon (Si), and is usable at high temperature and high voltage. Moreover, since a film of the oxide semiconductor is allowed to be formed with use of a sputtering method at a low temperature from about 300° C. to about 500° C., the film is allowed to be easily formed on a substrate made of glass. Further, in a case where the oxide semiconductor is used as a driving device of a display, electron mobility of the driving device is 10 or more times as high as a TFT using amorphous silicon. In addition thereto, as described above, since the oxide semiconductor has a wide band gap, the oxide semiconductor has a low intrinsic carrier concentration, thereby exhibiting superior off characteristics. Development of application of a TFT using such an oxide semiconductor to a large-screen, high-definition, and high-frame-rate liquid crystal display, an organic EL (electroluminescence) display, and the like has been advanced.

### SUMMARY

In a TFT, when a voltage equal to or higher than a predetermined threshold value is applied to a gate electrode, a carrier flow through an oxide semiconductor. Accordingly, a current flows between a source electrode and a drain electrode of the TFT to allow the TFT to perform an ON operation. On the other hand, when the TFT performs an OFF operation, a large voltage is applied between the gate electrode and the drain electrode. Therefore, a portion having a high electric field may be locally produced in a part of the oxide semiconductor, thereby impairing reliability of the TFT.

It is desirable to provide a semiconductor device, a display unit, and an electronic apparatus each of which has high reliability.

According to an embodiment of the present technology, there is provided a first semiconductor device including: an oxide semiconductor film; a gate insulating film; and a gate electrode, the oxide semiconductor film, the gate insulating film, and the gate electrode being provided in this order on a substrate, in which a thick-film section is provided in one or both of end portions of the gate insulating film, the thick-film section having a larger thickness than a thickness of a portion other than the thick-film section of the gate insulating film.

According to an embodiment of the present technology, there is provided a first display unit provided with a display device and a semiconductor device, the semiconductor device configured to drive the display device, the semiconductor device including: an oxide semiconductor film; a gate insulating film; and a gate electrode, the oxide semiconductor film, the gate insulating film, and the gate electrode being provided in this order on a substrate, in which a thick-film section is provided in one or both of end portions of the gate insulating film, the thick-film section having a larger thickness than a thickness of a portion other than the thick-film section of the gate insulating film.

According to an embodiment of the present technology, there is provided a first electronic apparatus provided with a display unit, the display unit including a display device and a semiconductor device, the semiconductor device configured to drive the display device, the semiconductor device including: an oxide semiconductor film; a gate insulating film; and a gate electrode, the oxide semiconductor film, the gate insulating film, and the gate electrode being provided in this order on a substrate, in which a thick-film section is provided in one or both of end portions of the gate insulating film, the thick-film section having a larger thickness than a thickness of a portion other than the thick-film section of the gate insulating film.

The first semiconductor device, the first display unit, and the first electronic apparatus according to the embodiments of the present technology, the thick-film section is provided in the end portion of the gate insulating film; therefore, a distance between the gate electrode and the oxide semiconductor film through the thick-film section is longer than a distance between the gate electrode and the oxide semiconductor film through a portion other than the thick-film section of the gate insulating film.

According to an embodiment of the present technology, there is provided a second semiconductor device including: a gate electrode; an oxide semiconductor film including a channel region facing the gate electrode; and a gate insulating film provided between the gate electrode and the semiconductor film, in which a low-dielectric constant section is provided in one or both of end portions of the gate insulating film, the low-dielectric constant section having a smaller dielectric constant than that of a portion other than the low-dielectric constant section of the gate insulating film.

According to an embodiment of the present technology, there is provided a second display unit provided with a display device and a semiconductor device, the semiconductor device configured to drive the display device, the semiconductor device including: a gate electrode; an oxide semiconductor film including a channel region facing the gate electrode; and a gate insulating film provided between the gate electrode and the semiconductor film, in which a low-dielectric constant section is provided in one or both of end portions of the gate insulating film, the low-dielectric constant section having a smaller dielectric constant than that of a portion other than the low-dielectric constant section of the gate insulating film.

According to an embodiment of the present technology, there is provided a second electronic apparatus provided with a display unit, the display unit including a display device and a semiconductor device, the semiconductor device configured to drive the display device, the semiconductor device including: a gate electrode; an oxide semiconductor film including a channel region facing the gate electrode; and a gate insulating film provided between the gate electrode and the semiconductor film, in which a low-dielectric constant section is provided in one or both of end portions of the gate insulating film, the low-dielectric constant section having a smaller dielectric constant than that of a portion other than the low-dielectric constant section of the gate insulating film.

In the second semiconductor device, the second display unit, and the second electronic apparatus according to the embodiments of the present technology, the low-dielectric constant section is provided in the end portion of the gate insulating film; therefore, compared to a case where the low-dielectric constant section is not provided, an electric field generated in a portion close to the low-dielectric constant section of the oxide semiconductor film is relaxed.

In the first semiconductor device, the first display unit, and the first electronic apparatus according to the embodiments of the present technology, the thick-film section is provided in the end portion of the gate insulating film, and in the second semiconductor device, the second display unit, and the second electronic apparatus according to the embodiments of the preset technology, the low-dielectric constant section is provided in the end portion of the gate insulating film; therefore, concentration of an electric field on a portion close to the thick-film section or the low-dielectric constant section of the oxide semiconductor film is allowed to be suppressed. Accordingly, reliability is allowed to be improved. It is to be noted that effects of the embodiments of the present technology are not limited to effects described here, and may include any effect described in this description.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the technology, and are incorporated in and constitute a part of this specification. The drawings illustrate embodiments and, together with the specification, serve to explain the principles of the technology.

FIG. 1 is a sectional view illustrating a configuration of a semiconductor device according to a first embodiment of the present technology.

FIG. 2A is a sectional view illustrating a process of a method of manufacturing the semiconductor device illustrated in FIG. 1.

FIG. 2B is a sectional view illustrating a process following FIG. 2A.

FIG. 2C is a sectional view illustrating a process following FIG. 2B.

FIG. 3A is a sectional view illustrating a process following FIG. 2C.

FIG. 3B is a sectional view illustrating a process following FIG. 3A.

FIG. 4A is a sectional view illustrating a process following FIG. 3B.

FIG. 4B is a sectional view illustrating a process following FIG. 4A.

FIG. 4C is a sectional view illustrating a process following FIG. 4B.

FIG. 5 is a sectional view illustrating a configuration of a semiconductor device according to Comparative Example 1.

FIG. 6 is a sectional view illustrating a configuration of a semiconductor device according to Comparative Example 2.

FIG. 7 is a diagram illustrating current-voltage characteristics of the semiconductor device illustrated in FIG. 1.

FIG. 8A is a diagram illustrating a voltage in proximity to an end portion of a gate insulating film illustrated in FIG. 5.

FIG. 8B is a diagram illustrating a voltage in proximity to an end portion of a gate insulating film illustrated in FIG. 6.

FIG. 8C is a diagram illustrating a voltage in proximity to an end portion of a gate insulating film illustrated in FIG. 1.

FIG. 9A is a diagram illustrating an electric field in proximity to the end portion of the gate insulating film illustrated in FIG. 5.

FIG. 9B is a diagram illustrating an electric field in proximity to the end portion of the gate insulating film illustrated in FIG. 6.

FIG. 9C is a diagram illustrating an electric field in proximity to the end portion of the gate insulating film illustrated in FIG. 1.

FIG. 10 is a diagram illustrating magnitude of an electric field generated in the interior of an oxide semiconductor film illustrated in FIG. 1.

FIG. 11 is a sectional view illustrating a configuration of a semiconductor device according to Modification Example 1.

FIG. 12 is a diagram illustrating current-voltage characteristics of the semiconductor device illustrated in FIG. 11.

FIG. 13 is a diagram illustrating an electric field in proximity to an end portion of a gate insulating film illustrated in FIG. 11.

FIG. 14 is a diagram illustrating magnitude of an electric field generated in the interior of an oxide semiconductor film illustrated in FIG. 11.

FIG. 15 is a sectional view illustrating another example of the semiconductor device illustrated in FIG. 11.

FIG. 16 is a sectional view illustrating still another example of the semiconductor device illustrated in FIG. 11.

FIG. 17 is a sectional view illustrating a configuration of a semiconductor device according to Modification Example 2.

FIG. 18 is a diagram illustrating current-voltage characteristics of the semiconductor device illustrated in FIG. 17.

FIG. 19 is a sectional view illustrating another example of the semiconductor device illustrated in FIG. 17.

FIG. 20 is a diagram illustrating current-voltage characteristics of the semiconductor device illustrated in FIG. 19.

FIG. 21 is a sectional view illustrating a configuration of a semiconductor device according to a second embodiment of the present technology.

FIG. 22A is a sectional view illustrating a process of a method of manufacturing the semiconductor device illustrated in FIG. 21.

FIG. 22B is a sectional view illustrating a process following FIG. 22A.

FIG. 22C is a sectional view illustrating a process following FIG. 22B.

FIG. 23 is a diagram illustrating current-voltage characteristics of the semiconductor device illustrated in FIG. 21.

FIG. 24 is a diagram illustrating an electric field in proximity to an end portion of a gate insulating film illustrated in FIG. 21.

FIG. 25 is a diagram illustrating magnitude of an electric field generated in the interior of an oxide semiconductor film illustrated in FIG. 21.

FIG. 26 is a sectional view illustrating a configuration of a semiconductor device according to Modification Example 3.

FIG. 27 is a sectional view illustrating a configuration of a semiconductor device according to Modification Example 4.

FIG. 28 is a diagram illustrating current-voltage characteristics of the semiconductor device illustrated in FIG. 27.

FIG. 29 is a sectional view illustrating another example of the semiconductor device illustrated in FIG. 27.

FIG. 30 is a sectional view illustrating an example of a configuration of a display unit including the semiconductor device illustrated in FIG. 1.

FIG. 31 is a diagram illustrating an entire configuration of the display unit illustrated in FIG. 30.

FIG. 32 is a diagram illustrating an example of a circuit configuration of a pixel illustrated in FIG. 31.

FIG. 33 is a perspective view illustrating an application example of the display unit illustrated in FIG. 30.

### DETAILED DESCRIPTION

Some embodiments of the present technology will be described in detail below referring to the accompanying drawings. It is to be noted that description will be given in the following order.

1. First Embodiment (Semiconductor device: an example in which a thick-film section is provided in a gate insulating film)

2. Modification Example 1 (An example in which a thickness of the thick-film section is uniform)

3. Modification Example 2 (An example in which thick-film sections are provided in two end portions of the gate insulating film)

4. Second Embodiment (Semiconductor device: an example in which a low-dielectric constant section is provided in a gate insulating film)

5. Modification Example 3 (An example in which a low-dielectric constant section is configured of a part of a low-dielectric constant film)

6. Modification Example 4 (An example in which low-dielectric constant sections are provided in two end portions of the gate insulating film)

5. Application Example (Display unit)

### First Embodiment

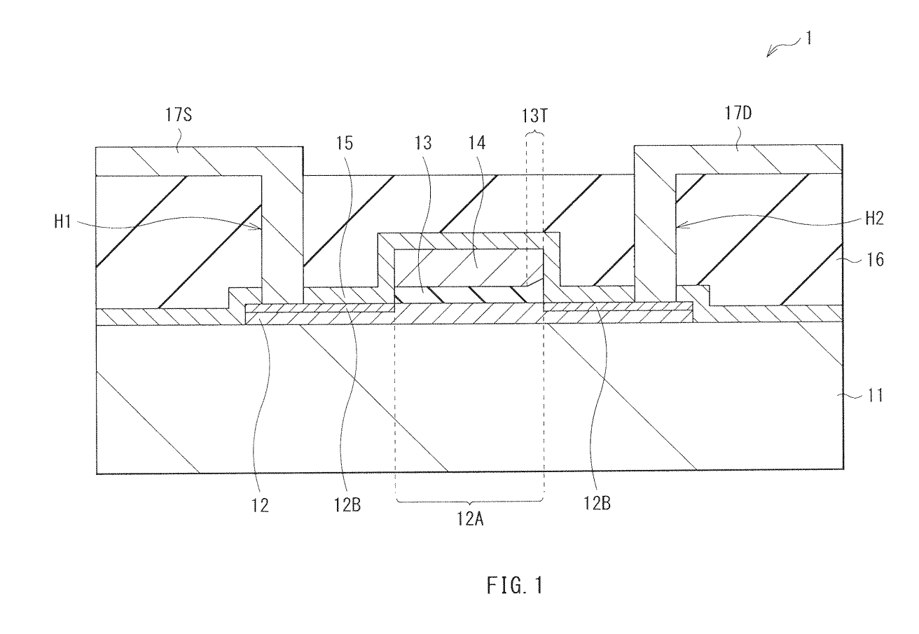

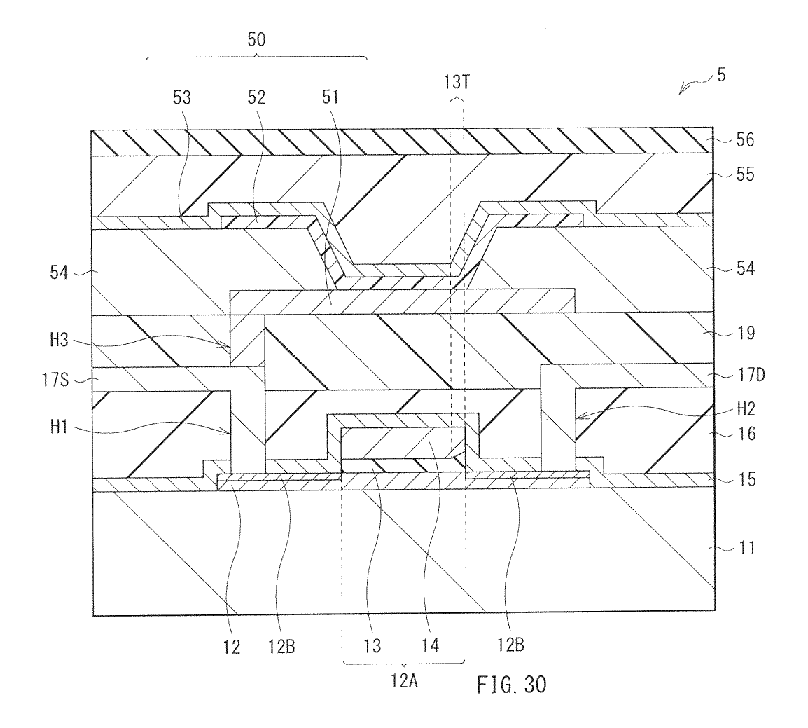

FIG. 1 illustrates a sectional configuration of a semiconductor device (a semiconductor device 1) according to a first embodiment of the present technology. In the semiconductor device 1, an oxide semiconductor film 12 is provided on a substrate 11, and the semiconductor device 1 includes a staggered (top-gate) TFT. A gate insulating film 13 and a gate electrode 14 are disposed in this order in a selective region on the oxide semiconductor film 12. A high-resistance film 15 and an interlayer insulating film 16 are so provided as to cover the oxide semiconductor film 12, the gate insulating film 13, and the gate electrode 14. A source electrode 17S and a drain electrode 17D are provided on the interlayer insulating film 16. Connection holes H1 and H2 that penetrate through the high-resistance film 15 and the interlayer insulating film 16 are provided in the high-resistance film 15 and the interlayer insulating film 16. The source electrode 17S is connected to a low-resistance region 12B that will be described later of the oxide semiconductor film 12 through the connection hole H1, and the drain electrode 17D is connected to the low-resistance region 12B of the oxide semiconductor film 12 through the connection hole H2. In the semiconductor device 1 including such a staggered TFT, the oxide semiconductor film 12 is allowed to be formed directly on the substrate 11, and the oxide semiconductor film 12 is covered with the gate electrode 14; therefore, the oxide semiconductor film 12 may be protectable from, for example, a layer disposed thereabove such as an organic layer (an organic layer 53 that will be described later in FIG. 30) including a light-emitting layer. Accordingly, the semiconductor device 1 may be suitably used as a display driving device.

The substrate 11 may be configured of, for example, a plate of a material such as quartz, glass, silicon, or a resin (plastic) film. Since the oxide semiconductor film 12 is formed by a sputtering method that will be described later without heating the substrate 11, a low-priced resin film may be used. Examples of the resin material may include PET (polyethylene terephthalate) and PEN (polyethylene naphtalate). In addition thereto, a metal substrate made of stainless steel (SUS) or the like including a film of an insulating material formed thereon may be used according to the intended use.

The oxide semiconductor film 12 is provided in a selective region on the substrate 11, and has a function as an active layer of a TFT. The oxide semiconductor film 12 may include, for example, as a main component, an oxide of one or more elements of indium (In), gallium (Ga), zinc (Zn), and tin (Sn). Specific examples of an amorphous oxide may include indium-tin-zinc oxide (ITZO) and indium-gallium-zinc oxide (IGZO: InGaZnO), and specific examples of a crystalline oxide may include zinc oxide (ZnO), indium-zinc oxide (IZO (registered trademark)), indium-gallium oxide (IGO), indium-tin oxide (ITO), and indium oxide (InO). Although either an amorphous oxide semiconductor material or a crystalline oxide semiconductor material may be used, the crystalline oxide semiconductor material may be preferably used, since etching selectivity to the gate insulating film 13 is allowed to be secured easily. A thickness (a thickness in a laminating direction, hereinafter simply referred to as “thickness”) of the oxide semiconductor film 12 may be, for example, about 50 nm.

In the oxide semiconductor film 12, a region overlapping the gate electrode 14 (a region facing the gate electrode 14) in a plan view serves as a channel region 12A. On the other hand, a part from a surface (a top surface) along a thickness direction of a region other than the channel region 12A of the oxide semiconductor film 12 serves as the low-resistance region 12B having lower electric resistivity than the channel region 12A. The low-resistance region 12B may be formed by allowing a metal such as aluminum (Al) to react with an oxide semiconductor material to diffuse the metal (a dopant) into the oxide semiconductor material. In the TFT of the semiconductor device 1, a self-aligned configuration is achieved by the low-resistance region 12B, and parasitic capacity formed in intersection regions between the gate electrode 14 and the source electrode 17S and between the gate electrode 14 and the drain electrode 17D is allowed to be reduced. Moreover, the low-resistance region 12B also has a role in stabilizing characteristics of the TFT.

The gate insulating film 13 is provided between the gate electrode 14 and the oxide semiconductor film 12, and may be configured of a single-layer film of one of a silicon oxide film (SiOx), a silicon nitride film (SiNx), a silicon oxynitride film (SiON), and an aluminum oxide film (AlOx), or a laminate film of two or more thereof. In particular, the silicon oxide film and the aluminum oxide film may be preferable, since the silicon oxide film and the aluminum oxide film are less likely to reduce the oxide semiconductor. In this embodiment, a thick-film section 13T is provided in one end portion of the gate insulating film 13. As will be described later, the thick-film section 13T is allowed to suppress concentration of an electric field on a portion close to the thick-film section 13T of the oxide semiconductor film 12.

The thick-film section 13T is provided along a side close to the drain electrode 17D of the gate insulating film 13. In other words, the thick-film section 13T is provided in an end portion close to the drain electrode 17D of the gate insulating film 13. The thick-film section 13T is a portion having a larger thickness than the other portion such as a central portion and a portion close to the source electrode 17S of the gate insulating film 13. The thickness of the thick-film section 13T is the smallest at a position closest to the central portion and is gradually increased toward an edge of the gate insulating film 13. A top surface (a contact surface with the gate electrode 14) of the thick-film section 13T may be preferably a smooth inclined surface. A thickness of the edge having the largest thickness of the gate insulating film 13 in the thick-film section 13T may be preferably about 1.5 times to about 3 times as large as the thickness of a portion other than the thick-film section 13T of the gate insulating film 13. The thickness of the edge having the largest thickness of the gate insulating film 13 in the thick-film section 13T is about 200 nm, and the thickness of the portion other than the thick-film section 13T of the gate insulating film 13 is about 100 nm. A distance (a distance along a channel length direction) of the thick-film section 13T may be preferably, for example, a length equal to or larger than the thickness of the gate insulating film 13, and about ½ or less of a gate length. For example, when the gate length is about 10 μm, the distance of the thick-film section 13T may be about 0.5 μm.

The gate electrode 14 is configured to control carrier density in the oxide semiconductor film 12 by a gate voltage (Vg) applied to the TFT, and has a function as a wiring line configured to supply an electric potential. The gate electrode 14 may be configured of, for example, a simple substance of one of molybdenum (Mo), titanium (Ti), aluminum, silver, neodymium (Nd), and copper (Cu), an alloy thereof, or a laminate film of two or more thereof. More specifically, a laminate configuration in which a low-resistance metal such as aluminum or silver is tucked in molybdenum or titanium, or an alloy (an Al—Nd alloy) of aluminum and neodymium may be adopted. Alternatively, the gate electrode 14 may be configured of a transparent conductive film such as ITO. A thickness of the gate electrode 14 may be, for example, about 200 nm. The gate electrode 14 and the gate insulating film 13 have the same planar shape as each other. An end portion close to the drain electrode 17D (a portion in contact with the thick-film section 13T of the gate electrode 13) of the gate electrode 14 may have a thickness equal to or thinner than that of the other portion of the gate electrode 14.

The high-resistance film 15 is a remaining oxidized metal film serving as a supply source of a metal that is diffused into the low-resistance region 12B of the oxide semiconductor film 12 in a manufacturing process that will be described later. The high-resistance film 15 may have, for example, a thickness of about 20 nm or less, and may be made of titanium oxide, aluminum oxide, indium oxide, tin oxide, or the like. Since such a high-resistance film 15 has superior barrier characteristics against outside air, in addition to the foregoing role in the process, the high-resistance film 15 also has a function of reducing an influence of oxygen and moisture that cause change in electrical characteristics of the oxide semiconductor film 12 in the semiconductor device 1. When the high-resistance film 15 is provided, the electrical characteristics of the semiconductor device 1 are allowed to be stabilized, and an effect of the interlayer insulating film 16 is allowed to be further improved.

In order to improve a barrier function, for example, a protective film made of aluminum oxide or silicon nitride with a thickness of about 30 nm to about 50 nm both inclusive may be laminated on the high-resistance film 15. Thus, the electrical characteristics of the oxide semiconductor film 12 in the semiconductor device 1 are further stabilized.

The interlayer insulating film 16 is laminated on the high-resistance film 15, and may be made of, for example, an organic material such as an acrylic-based resin, polyimide, a phenol-based resin, an epoxy-based resin, or a vinyl chloride-based resin. An inorganic material such as a silicon oxide film, a silicon nitride film, a silicon oxynitride film, or aluminum oxide may be used for the interlayer insulating film 16. Alternatively, a laminate of an organic material and an inorganic material may be used for the interlayer insulating film 16. The interlayer insulating film 16 including the organic material is allowed to be easily thickened to a thickness of, for example, about 1 μm to about 2 μm both inclusive. The thus-thickened interlayer insulating film 16 is allowed to sufficiently cover a level difference formed after processing of the gate electrode 14, thereby securing insulation. The interlayer insulating film 16 in which a silicon oxide film and an aluminum oxide film are laminated is allowed to suppress mixing and diffusion of moisture into the oxide semiconductor film 12. Thus, the electrical characteristics of the semiconductor device 1 are stabilized, and reliability of the semiconductor device 1 is improved.

Each of the source electrode 17S and the drain electrode 17D may have, for example, a thickness of about 200 nm to about 300 nm both inclusive, and may be made of a metal or a transparent conductive film similar to that described for the foregoing gate electrode 14. The source electrode 17S and the drain electrode 17D may be preferably made of, for example, a low-resistance metal such as aluminum or copper, and may be more preferably a laminate film configured by tucking such a low-resistance metal in a barrier layer made of titanium or molybdenum. Driving with less wiring delay is possible with use of such a laminate film. Moreover, in order to avoid formation of the parasitic capacity in the intersection regions between the gate electrode 14 and the source electrode 17S and between the gate electrode 14 and the drain electrode 17D, it may be desirable that the source electrode 17S and the drain electrode 17D be so provided as to avoid a region directly above the gate electrode 14.

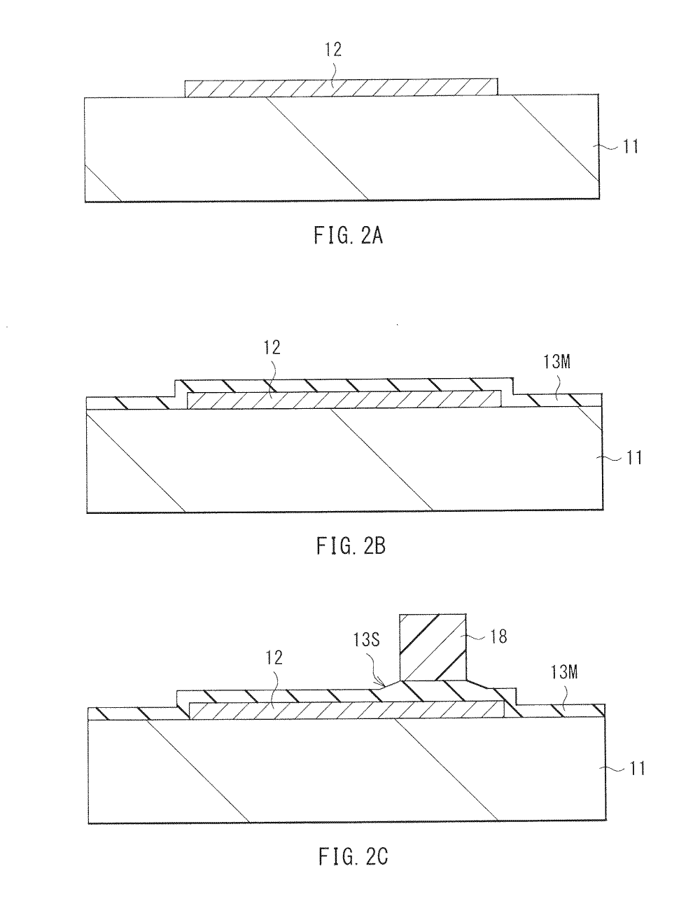

The semiconductor device 1 may be manufactured by, for example, the following procedure (refer to FIGS. 2A to 4C).

First, as illustrated in FIG. 2A, the oxide semiconductor film 12 made of the foregoing material is formed on the substrate 11. More specifically, first, an oxide semiconductor material film (not illustrated) is formed with, for example, a thickness of about 50 nm on an entire surface of the substrate 11 by, for example, a sputtering method. At this time, ceramic with a composition same as that of the oxide semiconductor that is to be formed in a film is used as a target. Moreover, since carrier concentration in the oxide semiconductor is highly dependent on oxygen partial pressure upon sputtering, the oxygen partial pressure is so controlled as to obtain desired transistor characteristics. When the oxide semiconductor film 12 is made of the foregoing crystalline material, etching selectivity in a process of etching the gate insulating film 13 that will be described later is allowed to be improved easily. Subsequently, pattering is performed on the formed oxide semiconductor material film by, for example, photolithography and etching to form the oxide semiconductor material film into a predetermined shape. At this time, processing may be preferably performed by wet etching using a mixed liquid of phosphoric acid, nitric acid, and acetic acid. The mixed liquid of phosphoric acid, nitric acid, and acetic acid allows a selection ratio with a base to be sufficiently increased, and allows for relatively easy processing.

After the oxide semiconductor film 12 is provided, as illustrated in FIG. 2B, an insulating material film 13M configured of a silicon oxide film or an aluminum oxide film with, for example, a thickness of about 200 nm is formed on the entire surface of the substrate 11. The insulating material film 13M is provided to form the gate insulating film 13. For example, a plasma CVD (Chemical Vapor Deposition) method may be used to form the insulating material film 13M. In addition to the plasma CVD method, the silicon oxide film may be formed by a reactive sputtering method. Moreover, when the aluminum oxide film is formed, in addition to the reactive sputtering method and the CVD method, an atomic layer deposition method may be used.

Subsequently, a resist pattern 18 is formed on the insulating material film 13M, and the insulating material film 13M is etched (refer to FIG. 2C). The resist pattern 18 is configured to form an inclined surface 13S in the insulating material film 13M, and the thick-film section 13T of the gate insulating film 13 is formed by the inclined surface 13S. In other words, an end portion of the gate insulating film 13 is formed close to a portion where the resist pattern 18 is provided. The inclined surface 13S is formed by etching the insulating material film 13M while gradually reducing the size of the resist pattern 18 (recessing the resist pattern 18). Etching on the insulating material film 13M may be performed by dry etching using, for example, fluorine-based gas such as perfluoromethane (CF₄), trifluoromethane (CHF₃), and hexafluoroethane (C₂F₆). The resist pattern 18 is allowed to be gradually reduced by performing dry etching on the insulating material film 13M with use of gas mixed with oxygen (O₂). Etching on the insulating material film 13M may be performed by wet etching using, for example, a buffered hydrofluoric acid liquid (a mixed liquid of ammonium fluoride (NH₄F) and hydrogen fluoride (HF)) to isotropically etch the insulating material film 13M. Etching on the insulating material film 13M may be performed, for example, until the smallest thickness thereof reaches about 100 nm.

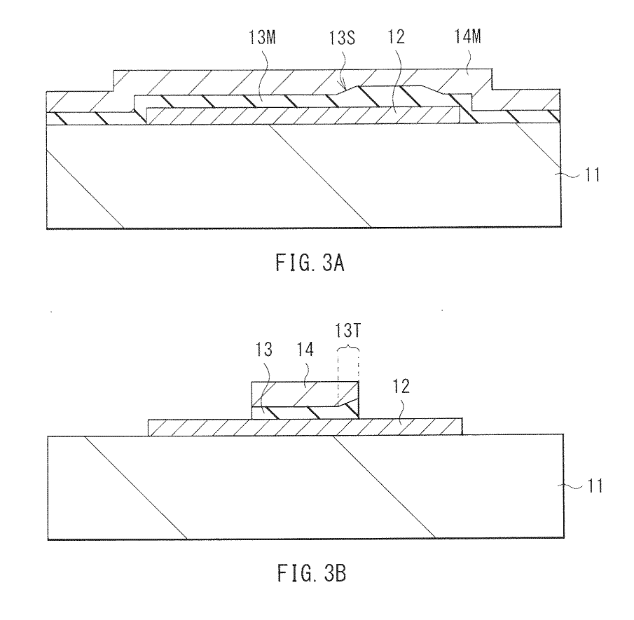

After the insulating material film 13M is etched, as illustrated in FIG. 3A, a conductive material film 14M made of molybdenum with a thickness of about 200 nm is formed on an entire surface of the insulating material film 13M by, for example, a sputtering method.

After the conductive material film 14M is formed, patterning is performed on the conductive material film 14M by, for example, photolithography and etching to form the gate electrode 14 in a selective region on the oxide semiconductor film 12. At this time, the inclined surface 13S of the insulating material film 13M (the thick-film section 13T of the gate electrode 13) overlaps an end portion of the gate electrode 14 in a plan view. Subsequently, the insulating material film 13M is etched with use of the gate electrode 14 as a mask. At this time, in a case where the oxide semiconductor film 12 is made of a crystalline material such as ZnO, IZO, or IGO, when an extremely large etching ratio is maintained with use of hydrofluoric acid or the like, processing is allowed to be easily performed. Thus, patterning on the gate insulating film 13 is performed to form the gate insulating film 13 into a planar shape same as that of the gate electrode 14 (refer to FIG. 3B).

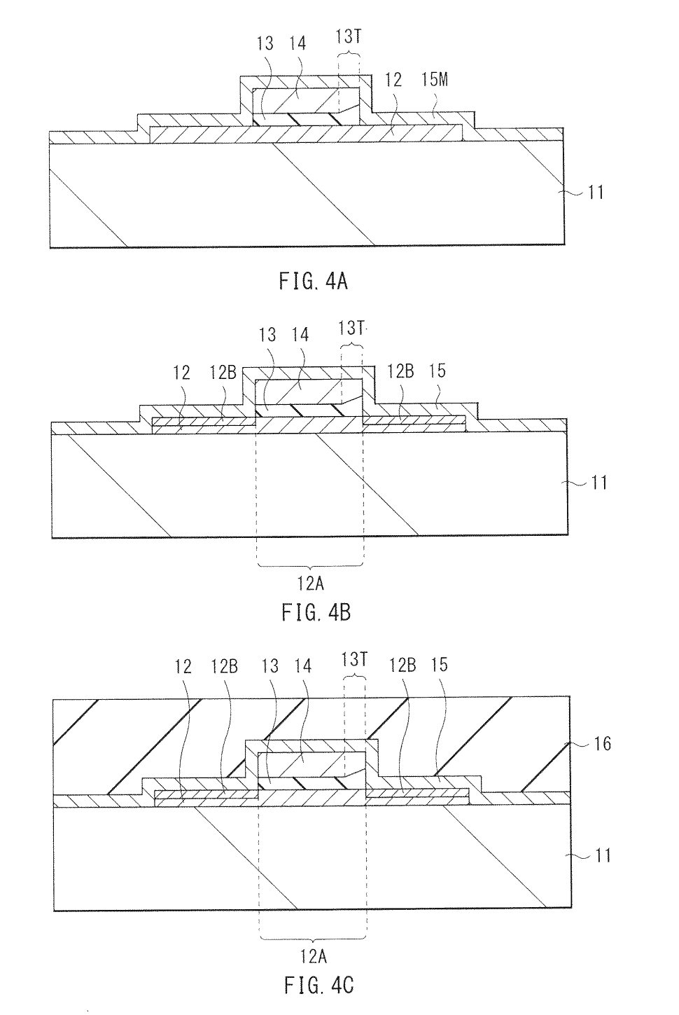

After the gate insulating film 13 is provided, as illustrated in FIG. 4A, a metal film 15M made of, for example, titanium, aluminum, tin, or indium is formed with, for example, a thickness of about 5 nm to about 10 nm both inclusive on the entire surface over the substrate 11 by, for example, a sputtering method or an atomic layer deposition method.

Subsequently, as illustrated in FIG. 4B, the metal film 15M is subjected to, for example, heat treatment at a temperature of about 300° C. to be oxidized, thereby forming the high-resistance film 15. At this time, the low-resistance region 12B is formed in a portion in contact with the high-resistance film 15 of the oxide semiconductor film 12, i.e., a region other than the channel region 12A of the oxide semiconductor film 12. The low-resistance region 12B is provided, for example, in a part (close to the high-resistance film 15) along the thickness direction of the oxide semiconductor film 12. A part of oxygen contained in the oxide semiconductor film 12 is used for oxidation reaction of the metal film 15M; therefore, oxygen concentration is decreased from a surface (a top surface) in contact with the metal film 15M of the oxide semiconductor film 12 with progress of oxidation of the metal film 15M. On the other hand, a metal such as aluminum is diffused from the metal film 15M into the oxide semiconductor film 12. The metal element functions as a dopant, and decreases resistance in a region in contact with the metal film 15M on the top surface side of the oxide semiconductor film 12. Thus, the low-resistance region 12B having lower electrical resistance than the channel region 12A is formed in self-aligning manner.

As heat treatment on the metal film 15M, as described above, the metal film 15M may be preferably annealed at a temperature of about 300° C. At this time, when annealing is performed in an oxidized gas atmosphere containing oxygen and the like, an excessive decrease in oxygen concentration in the low-resistance region 12B is allowed to be suppressed, and oxygen is allowed to be sufficiently supplied to the oxide semiconductor film 12. Thus, processes are allowed to be simplified by reducing later annealing processes.

The high-resistance film 15 may be formed by setting the temperature of the substrate 11 to a relatively high temperature when forming the metal film 15M on the substrate 11, instead of the forgoing annealing process. For example, in the process in FIG. 4A, when the metal film 15M is formed while the temperature of the substrate 11 is maintained at about 300° C., resistance in a predetermined region of the oxide semiconductor film 12 is allowed to be decreased without performing heat treatment. In this case, it is possible to decrease the carrier concentration in the oxide semiconductor film 12 to a necessary level for a transistor.

As described above, the metal film 15M may be preferably formed with a thickness of about 10 nm or less. When the thickness of the metal film 15M is about 10 nm or less, the metal film 15M is allowed to be completely oxidized (the high-resistance film 15 is allowed to be formed) by heat treatment. In a case where the metal film 15M is not completely oxidized, a process of removing the unoxidized metal film 15M by etching is necessary, since when the metal film 15M that is not sufficiently oxidized remains on the gate electrode 14 or the like, a leakage current may be generated. In a case where the metal film 15M is completely oxidized to form the high-resistance film 15, such a removing process is not necessary, thereby enabling simplification of manufacturing processes. In other words, generation of the leakage current is avoidable without performing the removing process by etching. It is to be noted that, in a case where the metal film 15M is formed with a thickness of about 10 nm or less, the thickness of the high-resistance film 15 after heat treatment is about 20 nm or less.

As a method of oxidizing the metal film 15M, in addition to the foregoing heat treatment, a method such as oxidation in a water-vapor atmosphere or plasma oxidation may be used. In particular, the plasma oxidation has the following advantage. After the high-resistance film 15 is formed, the interlayer insulating film 16 is formed by a plasma CVD method; however, the interlayer insulating film 16 is allowed to be formed subsequently (successively) after the plasma oxidation is performed on the high-resistance film 15. Therefore, there is an advantage that it is not necessary to increase the number of processes. It may be desirable that the plasma oxidation be performed by setting the temperature of the substrate 11 to about 200° C. to about 400° C. both inclusive, and generating plasma in a gas atmosphere containing oxygen such as mixed gas of oxygen and oxygen dinitride. Thus, the high-resistance film 15 with superior barrier characteristics against outside air is allowed to be formed, as described above.

After the high-resistance film 15 is formed, as illustrated in FIG. 4C, the interlayer insulating film 16 is formed on an entire surface of the high-resistance film 15. In a case where the interlayer insulating film 16 includes an inorganic insulating material, for example, a plasma CVD method, a sputtering method, or an atomic layer deposition method may be used, and in a case where the interlayer insulating film 16 includes an organic insulating material, for example, a coating method such as a spin coating method or a slit coating method may be used. The thickened interlayer insulating film 16 is allowed to be easily formed by the coating method. When the interlayer insulating film 16 is formed of aluminum oxide, for example, a reactive sputtering method using aluminum as a target by a DC or AC power supply may be used. After the interlayer insulating film 16 is provided, photolithography and etching are performed to form the connection holes H1 and H2 at predetermined positions in the interlayer insulating film 16 and the high-resistance film 15.

Subsequently, a conductive film (not illustrated) made of the material of the foregoing source electrode 17S and the foregoing drain electrode 17D is formed on the interlayer insulating film 16 by, for example, a sputtering method, and the connection holes H1 and H2 are filled with the conductive film. Thereafter, patterning is performed on the conductive film by, for example, photolithography and etching to form the conductive film into a predetermined shape. Thus, the source electrode 17S and the drain electrode 17D are formed on the interlayer insulating film 16, and the source electrode 17S and the drain electrode 17D are connected to the low-resistance region 12B of the oxide semiconductor film 12. The semiconductor device 1 illustrated in FIG. 1 is completed by the foregoing processes.

In the semiconductor device 1, when a voltage (a gate voltage) equal to or higher than a threshold voltage is applied to the gate electrode 14, a carrier flows through the channel region 12A of the oxide semiconductor film 12. Accordingly, a current (a drain current) flows between the source electrode 17S and the drain electrode 17D to perform an ON operation. On the other hand, in an OFF operation, a current does not flow between the source electrode 17S and the drain electrode 17D, and a large voltage is applied between the gate electrode 14 and the drain electrode 17D.

In this case, the thick-film section 13T is provided in the end portion close to the drain electrode 17D of the gate insulating film 13. Therefore, a distance between the oxide semiconductor film 12 and the gate electrode 14 through the thick-film section 13T is longer than a distance between the oxide semiconductor film 12 and the gate electrode 14 through the other portion of the gate insulating film 13. In other words, compared to a case where the thick-film section 13T is not provided, an electric field generated in a portion close to the thick-film section 13T of the oxide semiconductor film 12 is relaxed. This will be described below.

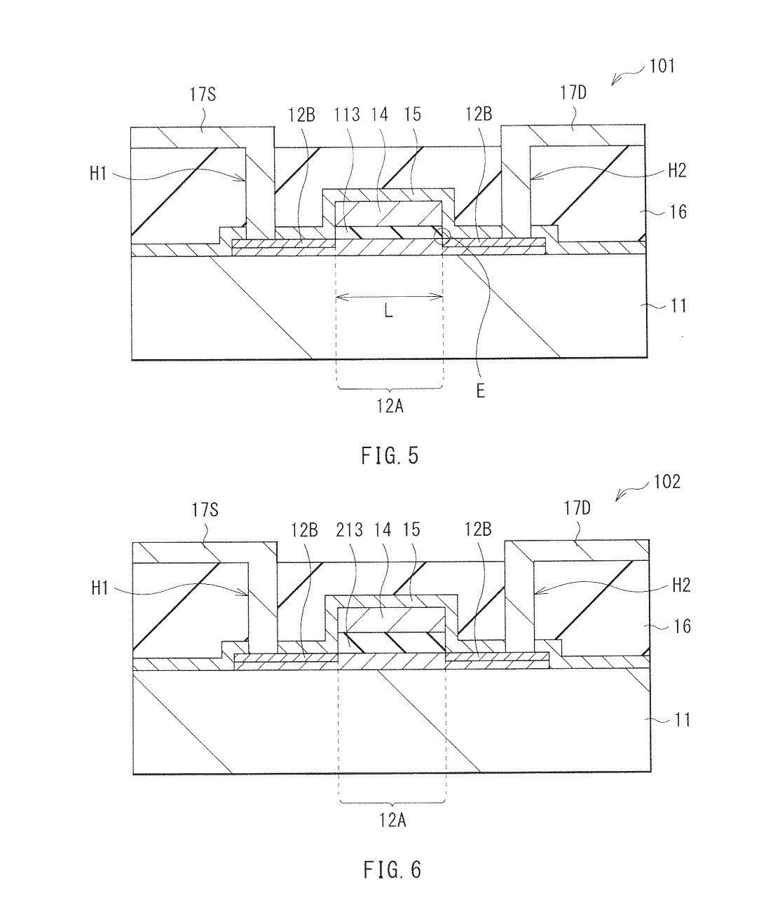

FIG. 5 illustrates a sectional configuration of a semiconductor device (a semiconductor device 101) according to Comparative Example 1. In the semiconductor device 101, a thickness of a gate insulating film 113 is uniform from an end close to the source electrode 17S to an end close to the drain electrode 17D. In other words, in the gate insulating film 113 of the semiconductor device 101, a thick-film section is not provided. When a large voltage is applied between the gate electrode 14 and the drain electrode 17D (the low-resistance region 12B to which the drain electrode 17 is connected) of the semiconductor device 101, a large voltage is applied to an end E close to the drain electrode 17D of the gate insulating film 113. Therefore, an electric field is locally concentrated on a portion close to the end E (around a boundary between the channel region 12A and the low-resistance region 12B) of the oxide semiconductor film 12. In particular, in the semiconductor device 101 with a self-aligned configuration, the low-resistance region 12B to which the drain electrode 17D is connected and the gate electrode 14 are disposed close to each other; therefore, a large electric field is more likely to be generated in the oxide semiconductor film 12. Such local concentration of an electric field on the oxide semiconductor film may cause a decrease in reliability.

A configuration of a semiconductor device (a semiconductor device 102) according to Comparative Example 2 is illustrated in FIG. 6. A gate insulating film 213 of the semiconductor device 102 has a thickness twice as large as that of the gate insulating film 113 of the semiconductor device 101. When the thickness of the entire gate insulating film 213 is increased, a distance between the oxide semiconductor film 12 and the gate electrode 14 is increased; therefore, the magnitude of an electric field generated in the oxide semiconductor film 12 is allowed to be decreased. However, in such a semiconductor device 102, magnitude of a drain current is decreased, and a current amount necessary for driving may not be secured.

On the other hand, in the semiconductor device 1, the thickness of the end portion close to the drain electrode 17D of the gate insulating film 13 is selectively increased (the thick-film section 13T). Therefore, magnitude of a drain current is maintained, and an electric field generated in the portion close to the thick-film section 13T of the oxide semiconductor film 12 is relaxed.

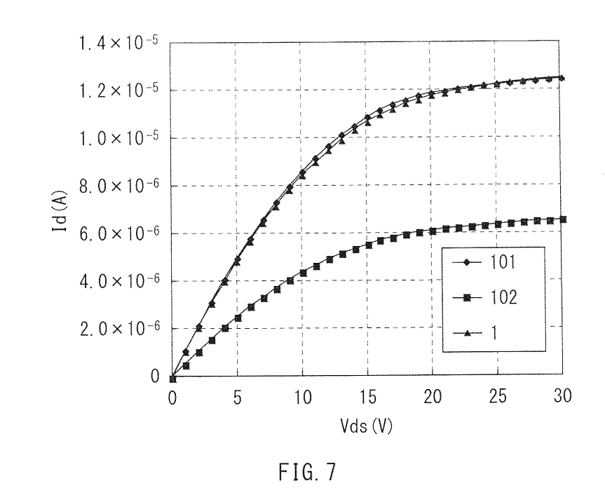

FIG. 7 illustrates current-voltage characteristics of the semiconductor devices 1, 101, and 102. In this case, measurement was performed by applying a voltage of 0 V and a voltage of 20 V to the source electrode 17S and the gate electrode 14, respectively, and changing a voltage applied to the drain electrode 17D. In FIG. 7, a horizontal axis indicates a drain-source voltage Vds, and a vertical axis indicates a drain current Id. The thickness of the oxide semiconductor film 12 of each of the semiconductor devices 1, 101, and 102 was 50 nm. The thickness of the gate insulating film 113 of the semiconductor device 101 was 100 nm, and the thickness of the gate insulating film 213 of the semiconductor device 102 was 200 nm. In the semiconductor device 1, the thickness of a portion other than the thick-film section 13T of the gate insulating film 13 was 100 nm, an edge of the thick-film section 13T was 200 nm, and the distance of the thick-film section 13T was 0.5 μm.

In the semiconductor device 102, the thickness of the gate insulating film 213 was larger than that of the gate insulating film 113; therefore, compared to the semiconductor device 101, the drain current of the semiconductor device 102 was reduced by about half. On the other hand, the drain current of the semiconductor device 1 was maintained at a level substantially equal to that of the drain current of the semiconductor device 101.

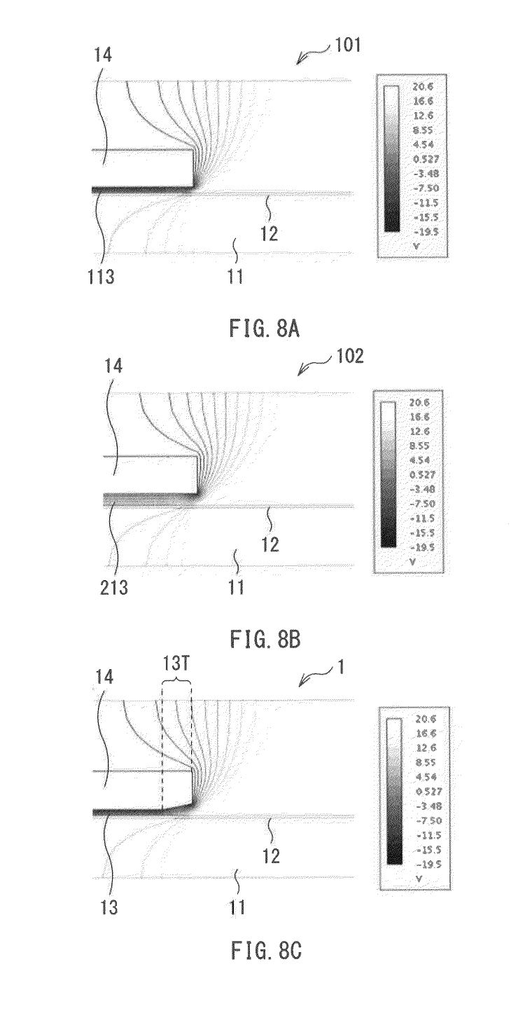

FIGS. 8A, 8B, and 8C illustrate results of simulations of a voltage applied to the semiconductor device 101, a voltage applied to the semiconductor device 102, and a voltage applied to the semiconductor device 1, respectively. The configurations of the semiconductor devices 1, 101, and 102 are similar to those described above in FIG. 7. The simulations were performed under conditions that 0 V, 20 V, and −20 V were applied to the source electrode 17S, the drain electrode 17D, and the gate electrode 14, respectively. In other words, a voltage difference between the gate electrode 14 and the drain electrode 17D was 40 V. While equipotential lines were concentrated on an end portion close to the drain electrode 17D of the gate insulating film 113 in the semiconductor device 101, a distribution of equipotential lines was moderate in the semiconductor device 102 and the semiconductor device 1.

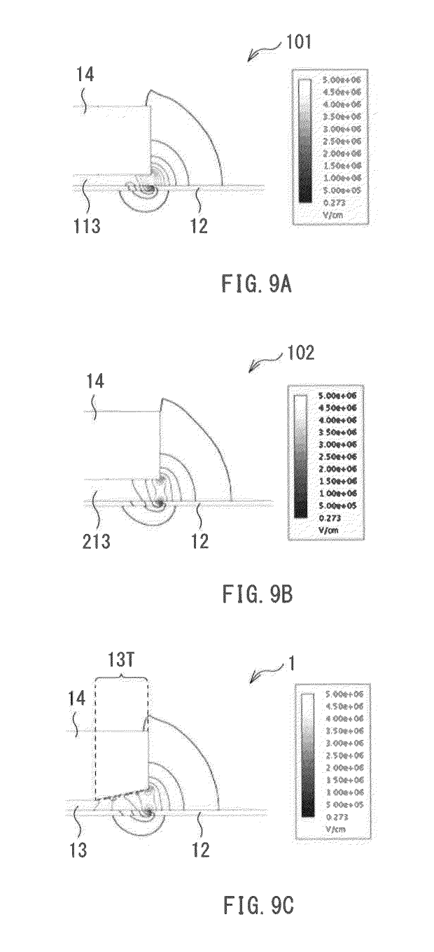

FIGS. 9A, 9B, and 9C illustrate results of simulations of electric fields generated in the semiconductor devices 1, 101, and 102 under the same conditions as those in FIGS. 8A, 8B, and 8C. FIGS. 9A, 9B, and 9C illustrate a result in the semiconductor device 101, a result in the semiconductor device 102, and a result in the semiconductor device 1, respectively.

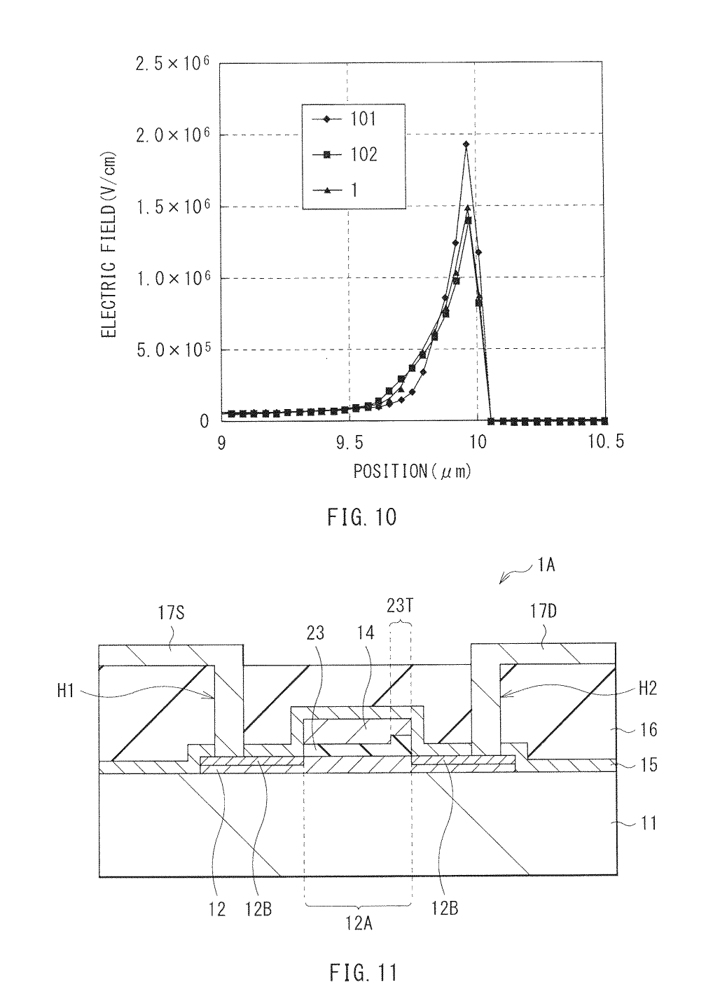

FIG. 10 illustrates the magnitude of an electric field generated inside the oxide semiconductor film 12, more specifically, the magnitude of an electric field generated at a position 10 nm along the thickness direction from a surface (a contact surface with the gate insulating film 13, 113, or 213) of the oxide semiconductor film 12, based on the simulation results in FIGS. 9A to 9C. In FIG. 10, a vertical axis indicates the magnitude of an electric field, and a horizontal axis indicates a position along the channel length direction of the oxide semiconductor film 12. At this time, a position of 0 μm on the horizontal axis indicates an edge close to the source electrode 17S of the channel region 12A, and a position of 10 μm indicates an edge close to the drain electrode 17D of the channel region 12A. In other words, the gate length was 10 μm.

As can be seen from FIGS. 9A to 9C and FIG. 10, in the semiconductor device 101, an electric field was concentrated on the vicinity of a boundary, at a position close to the drain electrode 17D, between the channel region 12A and the low-resistance region 12B in the oxide semiconductor film 12. On the other hand, in the semiconductor device 102 and the semiconductor device 1, compared to the semiconductor device 101, it was confirmed that local concentration of an electric field on the oxide semiconductor film 12 was suppressed. In the semiconductor device 1, the magnitude of a maximum electric field generated in the oxide semiconductor film 12 is allowed to be decreased by about 25%, compared to the semiconductor device 101 (refer to FIG. 10).

Thus, in this embodiment, the thick-film section 13T is provided in the end portion close to the drain electrode 17D of the gate insulating film 13; therefore, concentration of the electric field generated in the portion close to the thick-film section 13T of the oxide semiconductor film 12 is allowed to be suppressed. In particular, in the semiconductor device 1 with a self-aligned configuration, the electric field generated in the oxide semiconductor film 12 is easily increased; however, concentration of the electric field is allowed to be suppressed effectively. Therefore, reliability of the semiconductor device 1 is allowed to be improved. Moreover, since the thick-film section 13T is selectively provided in the end portion close to the drain electrode 17D of the gate insulating film 13, the magnitude of the drain current is allowed to be maintained.

Further, the top surface of the thick-film section 13T may be preferably formed into a smooth inclined surface by gradually increasing the thickness of the thick-film section 13T toward an edge thereof. Since an electric field tends to be concentrated on a corner, the corner is allowed to be reduced by providing such a thick-film section 13T, thereby further suppressing concentration of the electric field.

Modification examples of this embodiment and other embodiments will be described below. In the following description, like components are denoted by like numerals as of the foregoing embodiment, and will not be further described.

### Modification Example 1

FIG. 11 illustrates a sectional configuration of a semiconductor device (a semiconductor device 1A) according to Modification Example 1 of the foregoing first embodiment. In a gate insulating film (a gate insulating film 23) of the semiconductor device 1A, a thick-film section (a thick-film section 23T) with a uniform thickness is provided. Except for this, the semiconductor device 1A has a configuration similar to that of the semiconductor device 1 according to the foregoing embodiment, and functions and effects are similar to those of the semiconductor device 1 according to the foregoing embodiment.

The thick-film section 23T of the gate insulating film 23 is provided in an end portion close to the drain electrode 17D as with the thick-film section 13T. The thick-film section 23T is a portion with a larger thickness than that of the other portion of the gate insulating film 23.

The thickness of the thick-film section 23T is the same from a position close to a central portion to an edge of the gate insulating film 23. In the gate insulating film 23, a level difference is formed between the thick-film section 23T and a portion other than the thick-film section 23T (a portion with a smaller thickness than that of the thick-film section 23T), and the thick-film section 23T may have, for example, a substantially-right-angled corner section. The thick-film section 23T of such a gate insulating film 23 is allowed to be formed by etching the insulating material film 13M without forming the inclined surface 13S (refer to FIG. 2C). Therefore, in the thick-film section 23T having the corner section, there is a possibility that an electric field locally generated in the oxide semiconductor film 12 is slightly increased; however, the thick-film section 23T is allowed to be formed by a simple method.

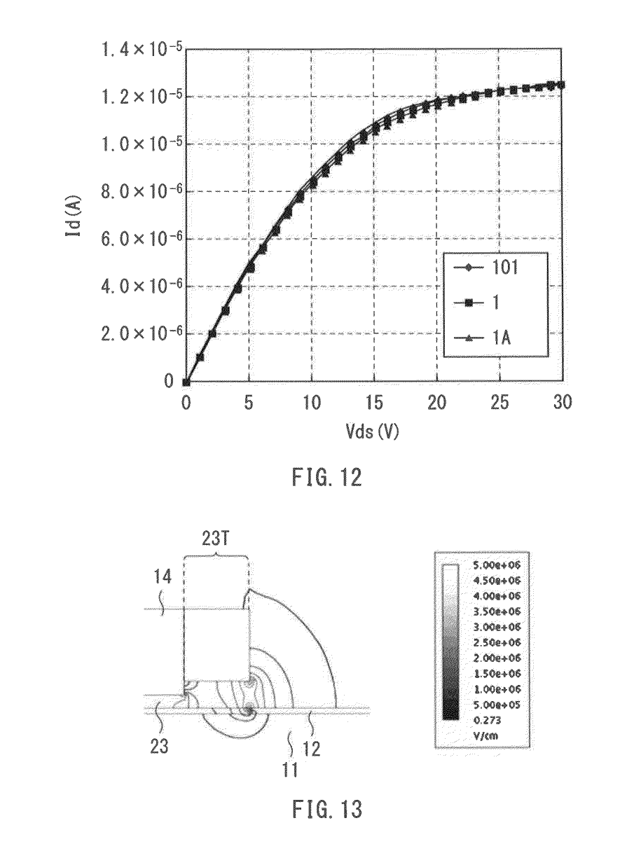

FIG. 12 illustrates current-voltage characteristics of the semiconductor device 1A together with those of the semiconductor devices 1 and 101. In FIG. 12, a horizontal axis indicates the drain-source voltage Vds, and a vertical axis indicate the drain current Id. The configurations of the semiconductor devices 1 and 101 and voltages of the respective components are similar to those described in FIG. 7. In the semiconductor device 1A, the thickness of the oxide semiconductor film 12 was 50 nm, the thickness of the portion other than the thick-film section 23T of the gate insulating film 23 was 100 nm, the thickness of the thick-film section 23T was 200 nm, and the distance of the thick-film section 23T was 0.5 μm.

It was confirmed that the magnitude of the drain current of the semiconductor device 1A was maintained at substantially the same level as the magnitude of the drain current in the semiconductor devices 1 and 101.

FIG. 13 illustrates a result of a simulation of an electric field generated in the semiconductor device 1A. The configuration of the semiconductor device 1A is similar to that described above in FIG. 12.

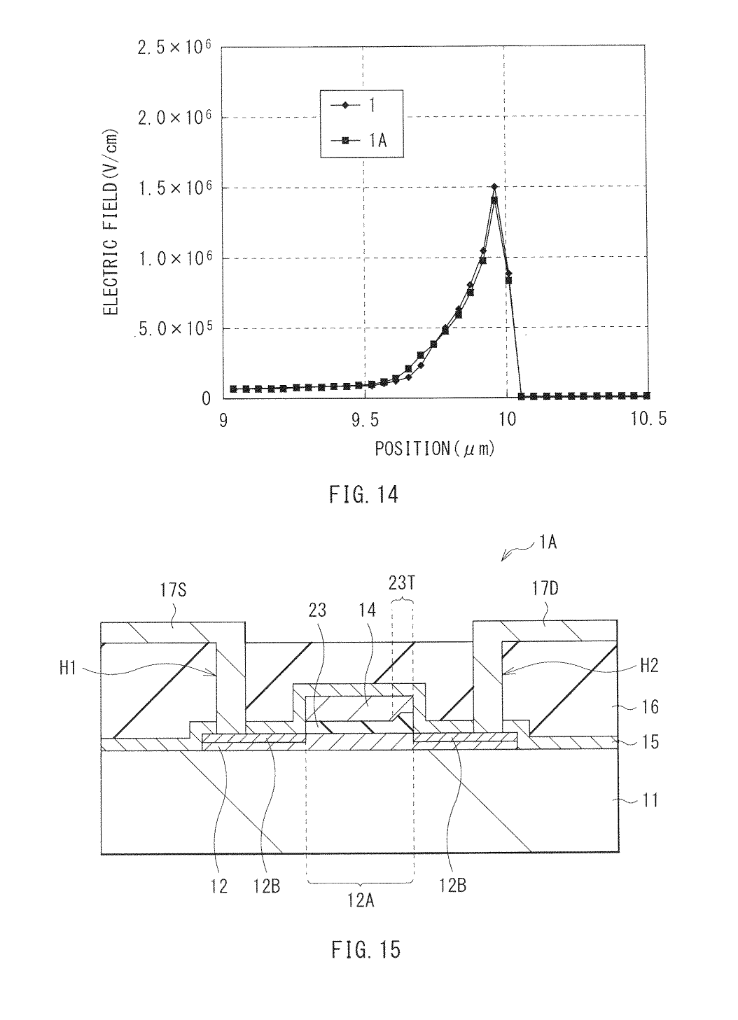

FIG. 14 illustrates the magnitude of an electric field generated inside the oxide semiconductor film 12, more specifically, the magnitude of an electric field generated at a position 10 nm along the thickness direction from the surface of the oxide semiconductor film 12. In FIG. 14, the magnitude of the electric field generated in the oxide semiconductor film 12 of the semiconductor device 1 is illustrated together with the result in the semiconductor device 1A. The configuration of the semiconductor device 1 is similar to that described above in FIG. 7. In FIG. 14, a vertical axis indicates the magnitude of an electric field, and a horizontal axis indicates a position along the channel length direction of the oxide semiconductor film 12. At this time, a position of 0 μm on the horizontal axis indicates an edge close to the source electrode 17S of the channel region 12A, and a position of 10 μm indicates an edge close to the drain electrode 17D of the channel region 12A. In other words, the gate length was 10 μm.

It was confirmed from FIGS. 13 and 14 that, even in the semiconductor device 1A, the electric field generated in a portion close to the thick-film section 23T of the oxide semiconductor film 12 was relaxed to substantially the same level as that in the semiconductor device 1 by providing the thick-film section 23T in the gate insulating film 23.

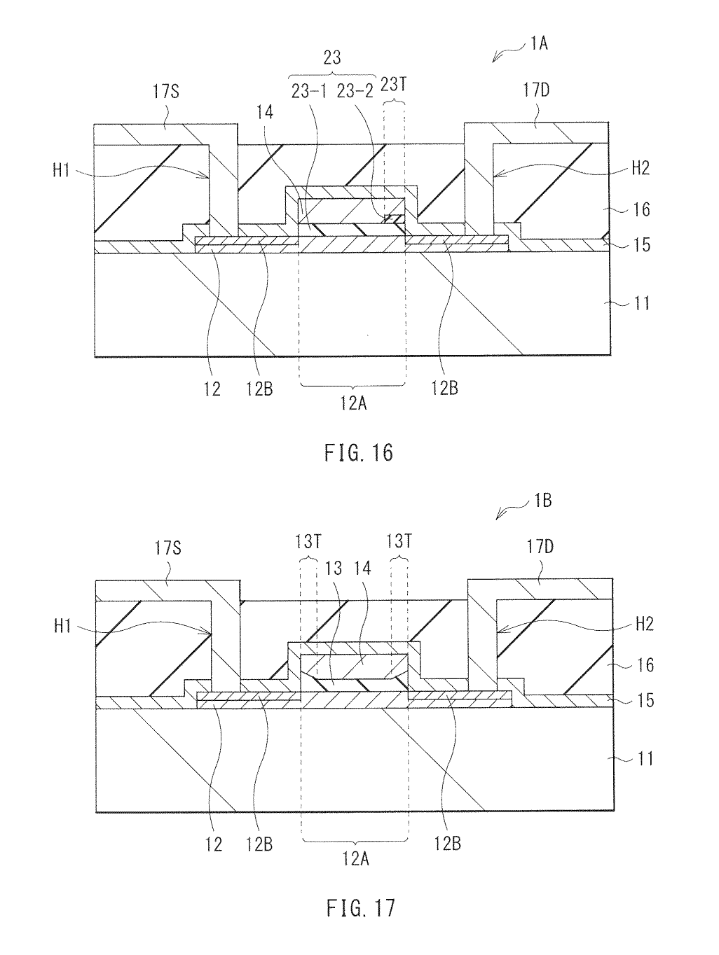

FIGS. 15 and 16 illustrate an example of the shape of the thick-film section 23T. The thick-film section 23T may have both a portion with a varying thickness and a portion with a uniform thickness (refer to FIG. 15). Alternatively, the thick-film section 23T may be configured of a laminate configuration of a gate insulating film 23-1 and a gate insulating film 23-2 (refer to FIG. 16). At this time, for example, the portion other than the thick-film section 23T of the gate insulating film 23 may be configured of the gate insulating film 23-1.

### Modification Example 2

FIG. 17 illustrates a sectional configuration of a semiconductor device (a semiconductor device 1B) according to Modification Example 2 of the foregoing first embodiment. In the semiconductor device 1B, the thick-film sections 13T are provided in both end portions of the gate insulating film 13. Except for this, the semiconductor device 1B has a configuration similar to that of the semiconductor device 1 according to the foregoing embodiment, and functions as effects are similar to those in the semiconductor device 1 according to the foregoing embodiment.

In the gate insulating film 13 of the semiconductor device 1B, the thick-film section 13T is also provided in an end portion close to the source electrode 17S in addition to the end portion close to the drain electrode 17D. In other words, the thick-film sections 13T are provided in a pair of end portions facing each other of the gate insulating film 13. The gate insulating film 13 with high symmetry is allowed to be formed by thus providing the thick-film sections 13T in both end portions of the gate insulating film 13. The gate insulating film 13 with a symmetric configuration is allowed to be formed with use of a self-aligning process by back exposure using a negative resist.

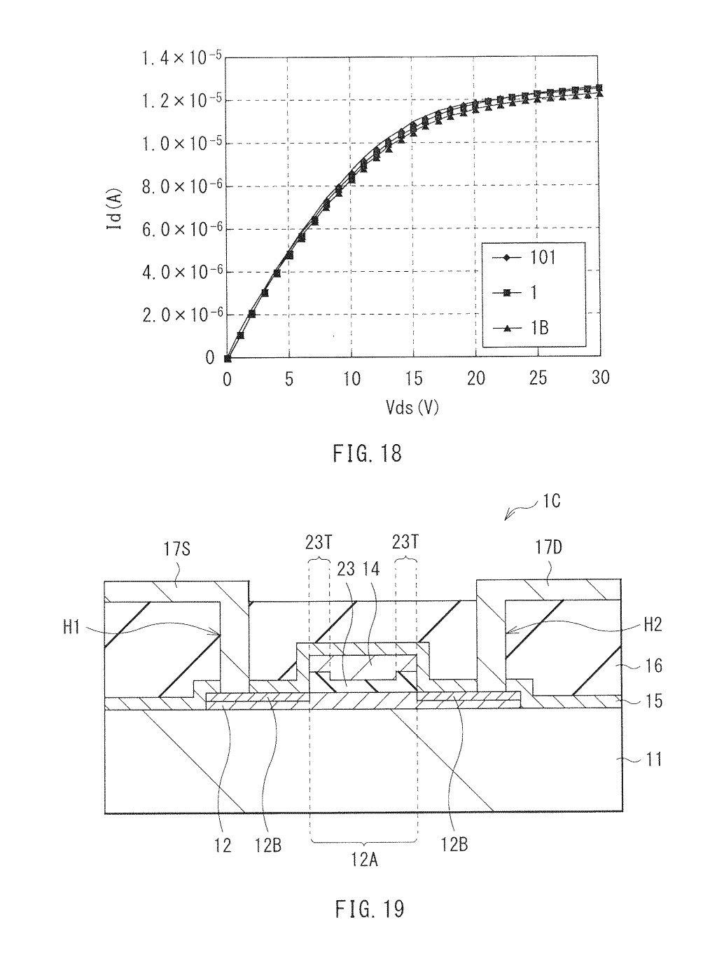

FIG. 18 illustrates current-voltage characteristics of the semiconductor device 1B together with the current-voltage characteristics of the semiconductor devices 1 and 101. In FIG. 18, a horizontal axis indicates the drain-source voltage Vds, and a vertical axis indicates the drain current Id. The configurations of the semiconductor devices 1 and 101 and voltages of respective components are similar to those described in FIG. 7. In the semiconductor device 1B, the thickness of the oxide semiconductor film 12 was 50 nm, a thickness of a portion other than the thick-film sections 13T of the gate insulating film 13 was 100 nm, and a thickness of an edge of each of the thick-film sections 13T on both sides was 200 nm, and the distance of the thick-film section 13T was 0.5 μm.

The magnitude of the drain current of the semiconductor device 1B was slightly decreased, compared to the magnitudes of the drain currents of the semiconductor devices 1 and 101. However, it was confirmed that an amount of decrease in the drain current of the semiconductor device 1B was smaller than that of the semiconductor device 102 (refer to FIG. 7), and even in the semiconductor device 1B in which two thick-film sections 13T were provided in the gate insulating film 13, the magnitude of the drain current was sufficiently maintained.

As illustrated in FIG. 19, the thick-film sections 23T with a uniform thickness may be provided in both end portions of the gate insulating film 23 (a semiconductor device 1C).

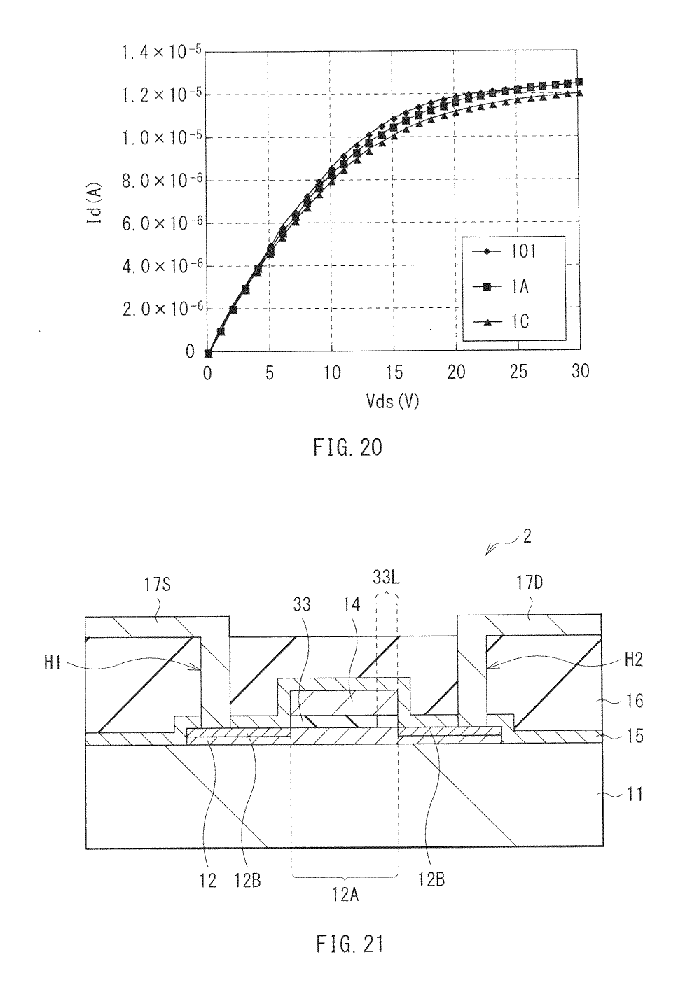

FIG. 20 illustrates current-voltage characteristics of the semiconductor device 1C together with the current-voltage characteristics of the semiconductor devices 1A and 101. In FIG. 20, a horizontal axis indicates the drain-source voltage Vds, and a vertical axis indicates the drain current Id. The configuration of the semiconductor device 101 is similar to that described in FIG. 7, and the configuration of the semiconductor device 1A is similar to that described in FIG. 12. In the semiconductor device 1C, the thickness of the oxide semiconductor film 12 was 50 nm, a thickness of the portion other than the thick-film sections 23T of the gate insulating film 23 was 100 nm, a thickness of each of the thick-film sections 23T on both sides was 200 nm, and the distance of the thick-film section 23T was 0.5 μm.

The magnitude of the drain current of the semiconductor device 1C was slightly decreased, compared to the magnitudes of the drain currents of the semiconductor devices 1A and 101. However, it was confirmed that an amount of decrease in the drain current of the semiconductor device 1C was smaller than that of the semiconductor device 102 (refer to FIG. 7), and even in the semiconductor device 1C in which two thick-film sections 23T were provided in the gate insulating film 23, the magnitude of the drain current was sufficiently maintained.

### Second Embodiment

FIG. 21 illustrates a sectional configuration of a semiconductor device (a semiconductor device 2) according to a second embodiment of the present technology. In the semiconductor device 2, a low-dielectric constant section (a low-dielectric constant section 33L) is provided in an end portion of a gate insulating film (a gate insulating film 33). Except for this, the semiconductor device 2 has a configuration similar to that of the semiconductor device 1 according to the foregoing first embodiment, and functions and effects are similar to those of the semiconductor device 1 according to the foregoing first embodiment.

The low-dielectric constant section 33L is provided in an end portion close to the drain electrode 17D of the gate insulating film 33. The low-dielectric constant section 33L is a portion having a lower dielectric constant than dielectric constants of the other portion such as a central portion and a portion close to the source electrode 17S of the gate insulating film 33. For example, the dielectric constant of the portion other than the low-dielectric constant section 33L of the gate insulating film 33 may be from about 3.0 to about 10.0 both inclusive, and the dielectric constant of the low-dielectric constant section 33L is about 1.0. For example, a single-layer film of one of a silicon oxide film (SiOx), a silicon nitride film (SiNx), a silicon oxynitride film (SiON), and an aluminum oxide film (AlOx), or a laminate film of two or more thereof may be used for the portion other than the low-dielectric constant section 33L of the gate insulating film 33. The low-dielectric constant section 33L may be formed of, for example, air. In other words, the low-dielectric constant section 33L of the gate insulating film 33 is an air gap between the oxide semiconductor film 12 and the gate electrode 14, and the semiconductor device 2 has a hollow configuration. A thickness of the low-dielectric constant section 33L is the same as that of the portion other than the low-dielectric constant section 33L of the gate insulating film 33. A distance of the low-dielectric constant section 33L (a distance along a channel length direction) may be preferably, for example, a length equal to or larger than the thickness of the gate insulating film 33, and about ½ or less of a gate length. For example, when the gate length is about 10 μm, the distance of the low-dielectric constant section 33L may be about 0.5 μm. A sectional shape of the low-dielectric constant section 33L may be any shape, for example, a square shape.

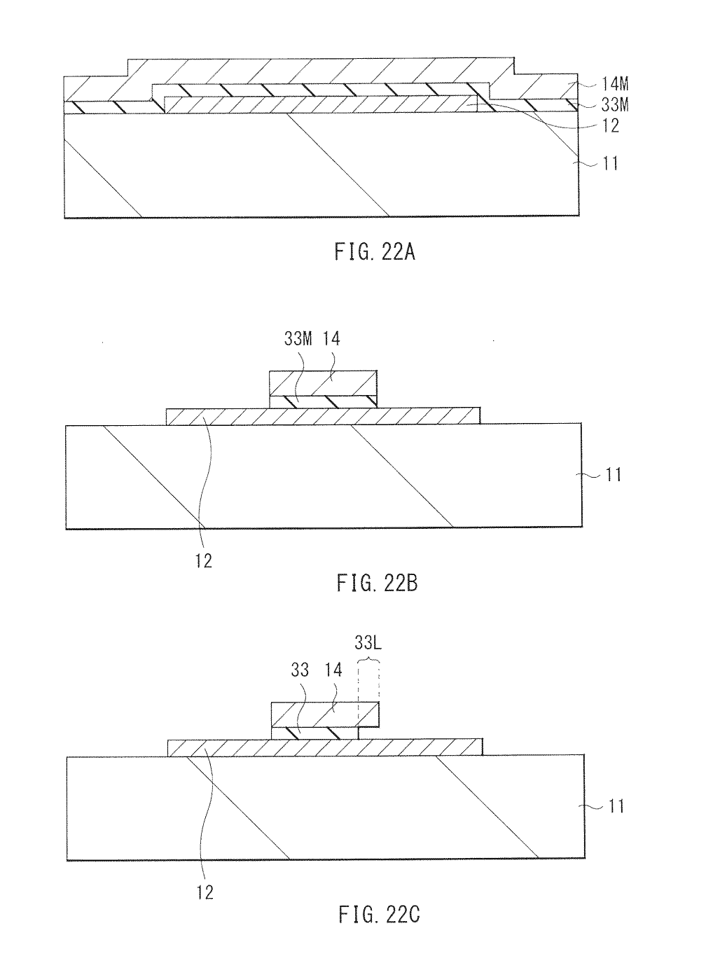

The gate insulating film 33 including such a low-dielectric constant section 33L may be formed by, for example, the following procedure (refer to FIGS. 22A to 22C).

First, after the oxide semiconductor film 12 is provided as with the semiconductor device 1 (refer to FIG. 2A), an insulating material film 33M and a conductive material film 14M are formed in this order (refer to FIG. 22A). Subsequently, patterning is performed on the conductive material film 14M by, for example, photolithography and etching to form the gate electrode 14. Subsequently, the insulating material film 33M is etched with use of the gate electrode 14 as a mask (refer to FIG. 22B). After that, a side surface of the insulating material film 33M is isotropically etched with use of, for example, wet etching using hydrofluoric acid, a buffered hydrofluoric acid solution, or the like. Thus, an air gap is formed directly below an end portion of the gate electrode 14 to form the low-dielectric constant section 33L (refer to FIG. 22C). In order to selectively provide the low-dielectric constant section 33L in one end portion of the gate insulating film 33, for example, it may be only necessary to protect the other end portion of the gate insulating film 33 with a photoresist or the like (not illustrated).

In the semiconductor device 2 in which the low-dielectric constant section 33L is selectively provided in the end portion of the gate insulating film 33, as with the semiconductor device 1, the magnitude of a drain current is maintained, and compared to a case where the low-dielectric constant section 33L is not provided, an electric field generated in a portion close to the low-dielectric constant section 33L of the oxide semiconductor film 12 is relaxed.

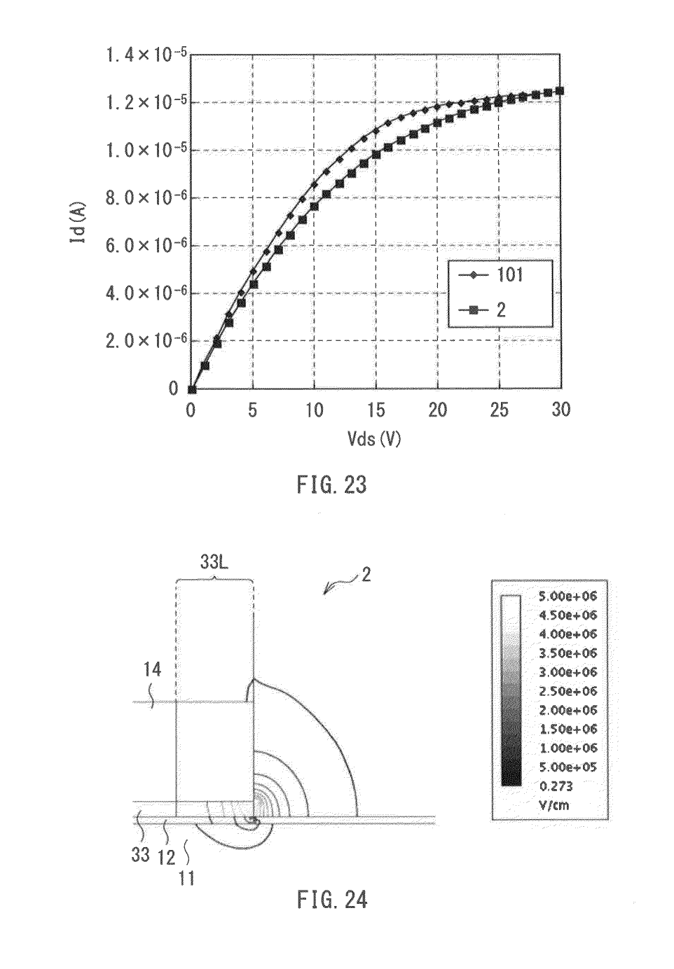

FIG. 23 illustrates current-voltage characteristics of the semiconductor device 2 together with the current-voltage characteristics of the semiconductor device 101. In FIG. 23, a horizontal axis indicates the drain-source voltage Vds, and a vertical axis indicates the drain current Id. The configuration of the semiconductor device 101 is similar to that described in FIG. 7. In the semiconductor device 2, the thickness of the oxide semiconductor film 12 was 50 nm, and the thickness of the gate insulating film 33 was 100 nm. The low-dielectric constant section 33L was formed of air, and the distance of the low-dielectric constant section 33L was 0.5 μm.

It was confirmed that the magnitude of the drain current of the semiconductor device 2 was maintained at substantially the same level as the magnitude of the drain current of the semiconductor device 101.

FIG. 24 illustrates a result of a simulation of an electric field generated in the semiconductor device 2. The configuration of the semiconductor device 2 is similar to that described above in FIG. 23.

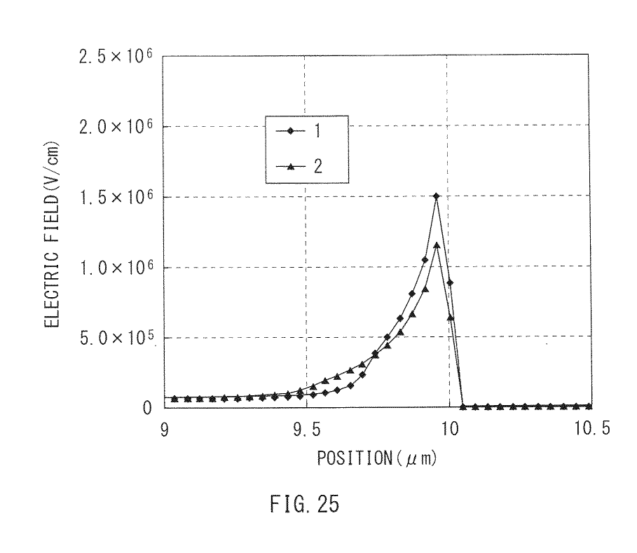

FIG. 25 illustrates the magnitude of an electric field generated inside the oxide semiconductor film 12, more specifically, the magnitude of an electric field generated at a position 10 nm along the thickness direction from the surface of the oxide semiconductor film 12. In FIG. 25, the magnitude of the electric field generated in the oxide semiconductor film 12 of the semiconductor device 1 is also illustrated together with the result in the semiconductor device 2. The configuration of the semiconductor device 1 is similar to that described above in FIG. 7. In FIG. 25, a vertical axis indicates the magnitude of an electric field, and a horizontal axis indicates a position along the channel length direction of the oxide semiconductor film 12. At this time, a position of 0 μm on the horizontal axis indicates an edge close to the source electrode 17S of the channel region 12A, and a position of 10 μm indicates an edge close to the drain electrode 17D of the channel region 12A. In other words, the gate length is 10 μm.

It was confirmed from FIGS. 24 and 25 that, even in the semiconductor device 2, the electric field generated in the portion close to the low-dielectric constant section 33L of the oxide semiconductor film 12 was relaxed by providing the low-dielectric constant section 33L in the gate insulating film 33. In the semiconductor device 2, the magnitude of a maximum electric field generated in the oxide semiconductor film 12 is allowed to be further decreased by about 20%, compared to the semiconductor device 1 (refer to FIG. 25).

### Modification Example 3

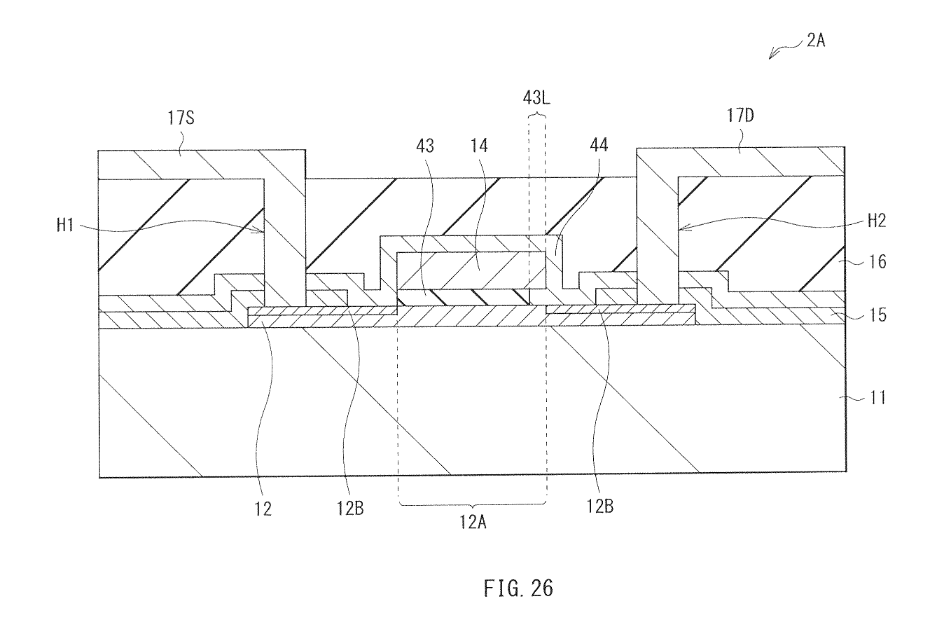

FIG. 26 illustrates a sectional configuration of a semiconductor device (a semiconductor device 2A) according to a modification example (Modification Example 3) of the foregoing second embodiment. In the semiconductor device 2A, a low-dielectric constant section (a low-dielectric constant section 43L) of a gate insulating film (a gate insulating film 43) is formed of a low-dielectric constant material other than air. Except for this, the semiconductor device 2A has a configuration similar to that of the semiconductor device 2 according to the foregoing second embodiment, and functions and effects are similar to those in the semiconductor device 2 according to the foregoing second embodiment.

The low-dielectric constant section 43L is provided in an end portion close to the drain electrode 17D of the gate insulating film 43. The low-dielectric constant section 43L may be configured of, for example, a portion of the low-dielectric constant film 44 having a lower dielectric constant than a dielectric constant of a portion other than the low-dielectric constant section 43L of the gate insulating film 43.

For example, after an air gap is provided directly below the end portion of the gage electrode 14 (refer to FIG. 22C), the low-dielectric constant film 44 may be so formed as to cover a side surface and a top surface of a laminate configured of the gate electrode 14 and the gate insulating film 43. In other words, the end portion of the gate insulating film 43 is covered with the low-dielectric constant film 44. Therefore, the low-dielectric constant film 44 enters the end portion of the gate insulating film 43 to form the low-dielectric constant section 43L. The low-dielectric constant film 44 may be formed by forming a silicon oxide (SiO₂) film doped with carbon (C), fluorine (F), or the like with use of, for example, a CVD method or the like.

### Modification Example 4

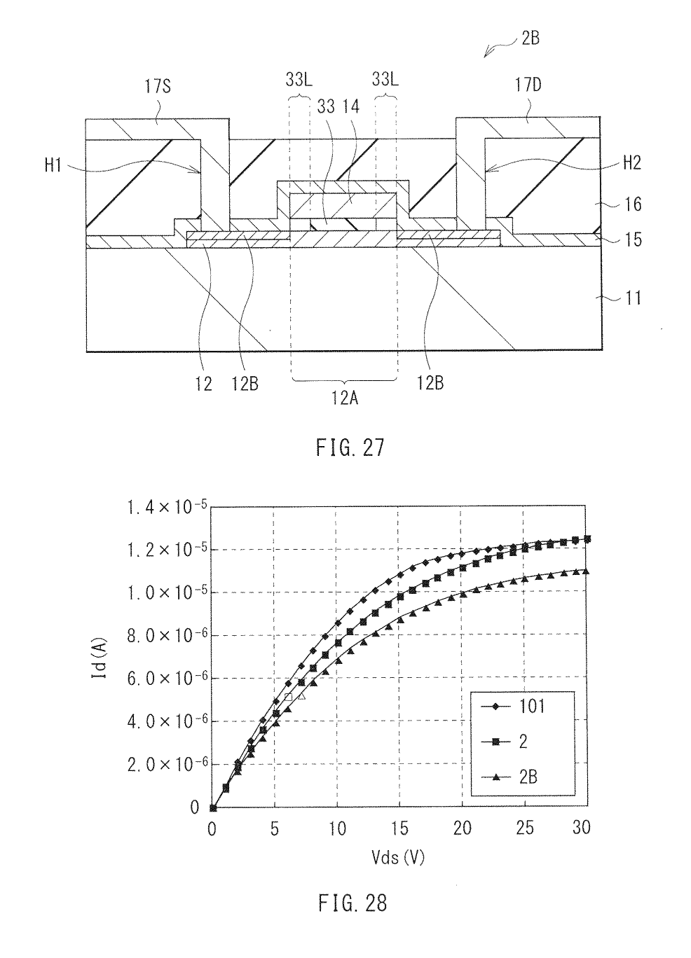

FIG. 27 illustrates a sectional configuration of a semiconductor device (a semiconductor device 2B) according to a modification example (Modification Example 4) of the foregoing second embodiment. In the semiconductor device 2B, the low-dielectric constant sections 33L are provided in both end portions of the gate insulating film 33. Except for this, the semiconductor device 2B has a configuration similar to that of the semiconductor device 2 according to the foregoing second embodiment, and functions and effects are similar to those in the semiconductor device 2 according to the foregoing second embodiment.

In the gate insulating film 33 of the semiconductor device 2B, the low-dielectric content section 33L is also provided in an end portion close to the source electrode 17S in addition to the end portion close to the drain electrode 17D. In other words, the low-dielectric constant sections 33L are provided in a pair of end portions facing each other of the gate insulating film 33. The gate insulating film 33 with high symmetry is allowed to be formed by thus providing the low-dielectric constant sections 33L in both end portions of the gate insulating film 33.

FIG. 28 illustrates current-voltage characteristics of the semiconductor device 2B together with the current-voltage characteristics of the semiconductor devices 2 and 101. In FIG. 28, a horizontal axis indicates the drain-source voltage Vds, and a vertical axis indicates the drain current Id. The configuration of the semiconductor device 101 is similar to that described in FIG. 7, and the configuration of the semiconductor device 2 is similar to that described in FIG. 23. In the semiconductor device 2B, the thickness of the oxide semiconductor film 12 was 50 nm, and a thickness of a portion other than the low-dielectric constant sections 33L of the gate insulating film 33 was 100 nm. The low-dielectric constant sections 33L are formed of air, and the distance of the low-dielectric constant section 33L was 0.5 μm.

The magnitude of the drain current of the semiconductor device 2B was slightly decreased, compared to the magnitudes of the drain currents of the semiconductor devices 2 and 101. However, it was confirmed that an amount of decrease in the drain current of the semiconductor device 2B was smaller than that of the semiconductor device 102 (refer to FIG. 7), and even in the semiconductor device 2B in which two low-dielectric constant sections 33L were provided in the gate insulating film 33, the magnitude of the drain current was sufficiently maintained.

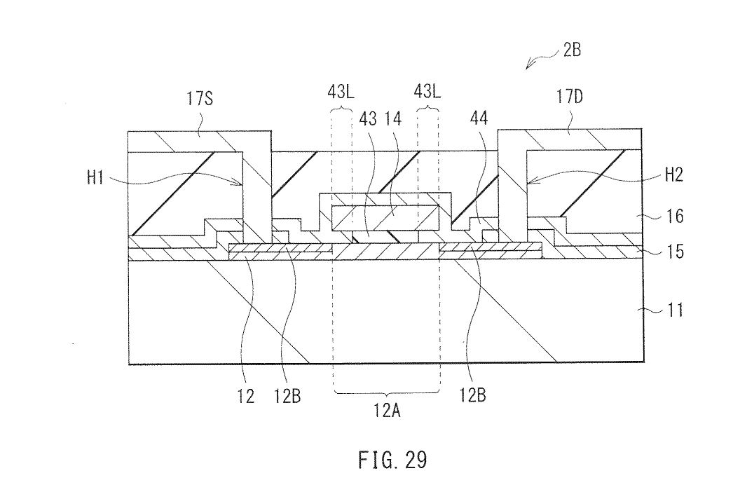

As illustrated in FIG. 29, the low-dielectric constant sections 43L formed of a low-dielectric constant material (the low-dielectric constant film 44) other than air may be provided in both end portions of the gate insulating film 43.

### Application Example

FIG. 30 illustrates a sectional configuration of a display unit (a display unit 5) including the foregoing semiconductor device 1 as a driving device. The display unit 5 is an active matrix organic EL (electroluminescence) display unit, and includes a plurality of the semiconductor devices 1 and a plurality of organic EL devices 50 driven by the semiconductor devices 1. In FIG. 30, a region (a sub-pixel) corresponding to one semiconductor device 1 and one organic EL device 50 is illustrated. FIG. 30 illustrates the display unit 5 including the semiconductor device 1; however, the display unit 5 may include one of the foregoing semiconductor devices 1A, 1B, 1C, 2A, and 2B instead of the semiconductor device 1.

The organic EL device 50 is provided on the semiconductor device 1 with a planarization film 19 in between. The organic EL device 50 includes a first electrode 51, an organic layer 52, and a second electrode 53 in this order from the planarization film 19, and is sealed by a protective layer (not illustrated). An inter-pixel insulating film 54 is provided on the first electrode 51. A sealing substrate 56 is bonded onto the protective layer with an adhesive layer 55 made of a thermosetting resin or an ultraviolet curable resin in between. The display unit 5 may be a bottom emission display unit in which light generated in the organic layer 52 is extracted from the substrate 11 or may be a top emission display unit in which light generated in the organic layer 52 is extracted from the sealing substrate 56.

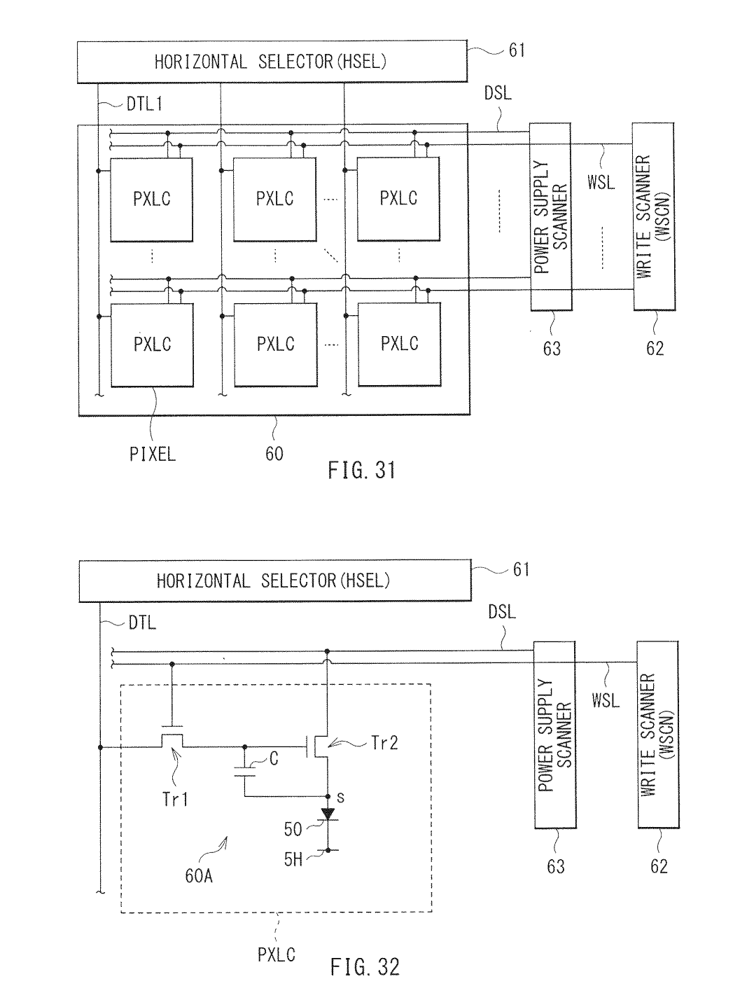

The planarization film 19 is provided in an entire display region (a display region 60 in FIG. 31 that will be described later) of the substrate 11 on the source electrode 17S, the drain electrode 17D, and the interlayer insulating film 16, and includes a connection hole H3. The connection hole H3 allows the source electrode 17S of the semiconductor device 1 and the first electrode 51 of the organic EL device 50 to be connected to each other. The planarization film 19 may be made of, for example, polyimide or an acrylic-based resin.

The first electrode 51 is so provided on the planarization film 19 as to fill the connection hole H3 therewith. The first electrode 51 may function as, for example, an anode, and is provided for each device. In a case where the display unit 5 is a bottom emission display unit, the first electrode 51 may be configured of a transparent conductive film, for example, a single-layer film made of one of indium-tin oxide (ITO), indium-zinc oxide (IZO), and the like, or a laminate film made of two or more thereof. On the other hand, in a case where the display unit 5 is top emission display unit, the first electrode 51 may be made of a reflective metal, for example, a single-layer film made of a metal simple substance of one of aluminum, magnesium (Mg), calcium (Ca), and sodium (Na) or an alloy including one or more thereof, or a multilayer film in which the metal simple substance or the alloy is laminated.

The first electrode 51 may be provided in contact with a surface (a surface close to the organic EL device 50) of the source electrode 17S. Accordingly, the planarization film 19 is allowed to be omitted, and the display unit 5 is allowed to be manufactured by less processes.

A pixel separation film 54 is provided to secure insulation between the first electrode 51 and the second electrode 53 and to separate light emission regions of respective devices from one another. The pixel separation film 54 includes respective openings facing the light emission regions of the respective devices. The pixel separation film 54 may be made of, for example, a photosensitive resin such as polyimide, an acrylic-based resin, or a novolac-based resin.

The organic layer 52 is so provided as to cover the openings of the pixel separation film 54. The organic layer 52 includes an organic electroluminescence layer (organic EL layer), and is configured to generate light in response to application of a driving current. The organic layer 52 may include, for example, a hole injection layer, a hole transport layer, the organic EL layer, and an electron transport layer in this order from the substrate 11 (the first electrode 51), and electrons and holes are recombined in the organic EL layer to cause light emission. The material of the organic EL layer is not specifically limited as long as the material of the organic EL layer is a typical low-molecular-weight material or a typical polymer material. For example, the organic EL layer configured to emit red light, green light, and blue light may be color-coded for respective devices, or an organic EL layer (for example, a laminate of a red organic EL layer, a green organic EL layer, and a blue organic EL layer) configured to emit white light may be provided on the entire surface of the substrate. The hole injection layer is configured to enhance hole injection efficiency and to suppress leakage. The hole transport layer is configured to enhance hole transport efficiency to the organic EL layer. Layers other than the organic EL layer such as the hole injection layer, the hole transport layer, and the electron transport layer may be provided as necessary.

The second electrode 53 may function as, for example, a cathode, and may be configured of a metal conductive film. In the case where the display unit 5 is a bottom emission display unit, the second electrode 53 may be configured of a reflective metal, for example, a single-layer film made of a metal simple substance of one of aluminum, magnesium (Mg), calcium (Ca), and sodium (Na) or an alloy including one or more thereof, or a multilayer film in which the metal simple substance or the alloy is laminated. On the other hand, in the case where the display unit is a top emission display unit, a transparent conductive film such as ITO or IZO may be used for the second electrode 53. For example, the second electrode 53 may be shared by the respective devices while being insulated from the first electrode 51.

The protective layer (not illustrated) may be made of an insulating material or a conductive material. Examples of the insulating material may include amorphous silicon (a-Si), amorphous silicon carbide (a-SiC), amorphous silicon nitride (a-Si_{(1-X)}Nx), and amorphous carbon (a-C).

The sealing substrate 56 is so disposed as to face the substrate 11 with the semiconductor device 1 and the organic EL device 50 in between. A material similar to that of the foregoing substrate 11 may be used for the sealing substrate 56. In the case where the display unit 5 is a top emission display unit, a transparent material may be used for the sealing substrate 56, and a color filter or a light-shielding film may be provided on the sealing substrate 56. In the case where the display unit 5 is a bottom emission display unit, the substrate 11 may be made of a transparent material, and, for example, a color filter or a light-shielding film may be provided on the substrate 11.

As illustrated in FIG. 31, the display unit 5 includes a plurality of pixels PXLC each of which includes such an organic EL device 50, and the pixels PXLC may be arranged in, for example, a matrix in a display region 60 on the substrate 11. A horizontal selector (HSEL) 61 as a signal line drive circuit, a write scanner (WSCN) 62 as a scanning line drive circuit, and a power supply scanner 63 as a power supply line drive circuit are provided around the display region 60.

In the display region 60, a plurality of (n-number of) signal lines DTL1 to DTLn are arranged along a column direction, and a plurality of (m-number of) scanning lines WSL1 to WSLm are arranged along a row direction. Moreover, the pixel PXLC (one of pixels corresponding to R, G, and B) is provided at each intersection of the signal line DTL and the scanning line WSL. Each signal line TDL is connected to the horizontal selector 61, and an image signal is supplied from the horizontal selector 61 to each pixel PXLC through the signal line DTL. Each scanning line WSL is electrically connected to the write scanner 62, and a scanning signal (a selection pulse) is supplied from the write scanner 62 to each pixel PXLC through the scanning line WSL. Each power supply line DTL is connected to the power supply scanner 63, and a power supply signal (a control pulse) is supplied from the power supply scanner 63 to each pixel PXLC through the power supply line DSL.

FIG. 32 illustrates a specific circuit configuration example in the pixel PXLC. Each pixel PXLC includes a pixel circuit 60A including the organic EL device 50. The pixel circuit 60A is an active drive circuit including a sampling transistor Tr1, a driving transistor Tr2, a capacitor device C, and the organic EL device 50. It is to be noted that one or both of the sampling transistor Tr1 and the driving transistor Tr2 correspond to the foregoing semiconductor device 1.

In the sampling transistor Tr1, a gate thereof is connected to the scanning line WSL corresponding thereto, one of a source and a drain thereof is connected to the signal line DTL corresponding thereto, and the other is connected to a gate of the driving transistor Tr2. In the driving transistor Tr2, a drain thereof is connected to the power supply line DSL corresponding thereto, and a source thereof is connected to an anode of the organic EL device 50. Moreover, a cathode of the organic EL device 50 is connected to a grounding wire 5H. It is to be noted that the grounding wire 5H is shared by all of the pixels PXLC. The capacitor device C is disposed between the source and the gate of the driving transistor Tr2.

The sampling transistor Tr1 is configured to be brought into conduction in response to a scanning signal (a selection pulse) supplied from the scanning line WSL, thereby sampling a signal potential of an image signal supplied from the signal line DTL and storing the signal potential in the capacitor device C. The driving transistor Tr2 is configured to receive a current supplied from the power supply line DSL that is set to a predetermined first potential (not illustrated) and to supply a driving current to the organic EL device 50 according to the signal potential stored in the capacitor device C. The organic EL device 50 is configured to emit light with luminance according to the signal potential of the image signal by the driving current supplied from the driving transistor Tr2.

In such a circuit configuration, the signal potential of the image signal supplied from the signal line DTL is sampled by brining the sampling transistor Tr1 into conduction in response to the scanning signal (the selection pulse) supplied from the scanning line WSL to be stored in the capacitor device C. Moreover, the current is supplied from the power supply line DSL that is set to the foregoing first potential to the driving transistor Tr2, and the driving current is supplied to the organic EL device 50 (each of the organic EL devices of red, green, and blue) in response to the signal potential stored in the capacitor device C. Then, each organic EL device 50 emits light with luminance according to the signal potential of the image signal by the supplied driving current. Thus, the display unit 5 displays an image, based on the image signal.

Such a display unit 5 may be formed by, for example, the following procedure.

First, as described above, the semiconductor device 1 is formed. Subsequently, the planarization film 19 made of the foregoing material is formed by, for example, a spin coating method or a slit coating method to cover the interlayer insulating film 16, the source electrode 17S, and the drain electrode 17D, and the connection hole H3 is formed in a part of a region facing the source electrode 17S of the planarization film 19.

Subsequently, the organic EL device 50 is formed on the planarization film 19. More specifically, the first electrode 51 made of the foregoing material is formed on the planarization film 19 by, for example, a spluttering method to fill the connection hole H3 therewith, and then patterning is performed on the first electrode 51 by photolithography and etching. After that, the pixel separation film 54 having openings are formed on the first electrode 51, and then the organic layer 52 is formed by, for example, a vacuum deposition method. Subsequently, the second electrode 53 made of the foregoing material is formed on the organic layer 52 by, for example, a sputtering method. Subsequently, the protective layer is formed on the second electrode 53 by, for example, a CVD method, and then the sealing substrate 56 is bonded onto the protective layer with use of the adhesive layer 55. Thus, the display unit 5 illustrated in FIG. 30 is completed.

In the display unit 5, for example, when a driving current according to an image signal of each color is applied to each pixel PXLC corresponding to one of R, G, and B, electrons and holes are injected into the organic layer 52 through the first electrode 51 and the second electrode 53. The electrons and the holes are recombined in the organic EL layer included in the organic layer 52 to cause light emission. Thus, in the display unit 5, for example, a full-color image of R, G, and B is displayed. Moreover, a charge corresponding to the image signal is stored in the capacitor device C by applying a potential corresponding to the image signal to an end of the capacitor device 44C upon the image display operation.

In this case, since the display unit 5 includes the semiconductor device 1 with high reliability, reliability of the display unit 5 is improved.

The display unit 5 is applicable to electronic apparatuses in any fields that display, as an image or a picture, an image signal inputted from outside or an image signal produced inside. Examples of the electronic apparatuses may include televisions, digital cameras, notebook personal computers, portable terminal devices such as mobile phones, and video cameras.

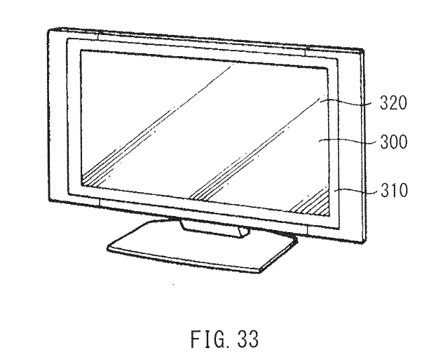

FIG. 33 illustrates an appearance of a television to which the foregoing display unit 5 is applied. This television may include, for example, an image display screen section 300 including a front panel 310 and a filter glass 320, and the image display screen section 300 is configured of the foregoing display unit 5.

Although the present technology is described referring to the embodiments and the modification examples, the present technology is not limited thereto, and may be variously modified. For example, in the foregoing embodiments and the like, a configuration provided with the high-resistance film 15 is described as an example; however, the high-resistance film 15 may be removed after forming the low-resistance region 12B. However, as described above, the case where the high-resistance film 15 is provided may be desirable, since electrical characteristics of the semiconductor device 1 are allowed to be stably maintained.

Moreover, in the foregoing embodiments and the like, the case where the low-resistance region 12B is provided in a part along the thickness direction from the surface (the top surface) of the oxide semiconductor film 12 is described; however, the low-resistance region 12B may be provided in a part along the thickness direction from the surface (the top surface) to a bottom surface of the oxide semiconductor film 12.

Further, in the foregoing second embodiment, the semiconductor device 1 including a top gate TFT is described (refer to FIG. 21); however, the semiconductor device 2 may include a bottom gate TFT.

In addition thereto, the material and thickness of each layer, the method and conditions of forming each layer are not limited to those described in the above-described embodiments and the like, and each layer may be made of any other material with any other thickness by any other method under any other conditions.

Furthermore, the present technology is applicable to display units using, in addition to the organic EL device, other display devices such as a liquid crystal display device, an electrophoretic display device, and an inorganic electroluminescence device.

In addition thereto, in the foregoing embodiments and the like, the display unit is described as an application example of the semiconductor device; however, the semiconductor device may be applied to an image detector and the like.

It is to be noted that the effects described in this description are merely examples; therefore, effects in the present technology are not limited thereto, and the present technology may have other effects.

It is to be noted that the present technology may have the following configurations.

(1) A semiconductor device including:

an oxide semiconductor film;

a gate insulating film; and

a gate electrode,

the oxide semiconductor film, the gate insulating film, and the gate electrode being provided in this order on a substrate,

in which a thick-film section is provided in one or both of end portions of the gate insulating film, the thick-film section having a larger thickness than a thickness of a portion other than the thick-film section of the gate insulating film.

(2) The semiconductor device according to (1), further including a source electrode and a drain electrode configured to be electrically connected to the oxide semiconductor film,

in which the thick-film section is provided in an end portion close to the drain electrode of the gate insulating film.

(3) The semiconductor device according to (2), in which the oxide semiconductor film includes a channel region and a low-resistance region provided in a portion other than the channel region, the channel region being disposed at a position overlapping the gate electrode in a plan view.

(4) The semiconductor device according to (3), in which the source electrode and the drain electrode are electrically connected to the low-resistance region of the oxide semiconductor film.

(5) The semiconductor device according to (3) or (4), further including a high-resistance film disposed in contact with the low-resistance region.

(6) The semiconductor device according to any one of (2) to (5), in which the thick-film section is further provided in an end portion close to the source electrode of the gate insulating film.

(7) The semiconductor device according to any one of (1) to (6), in which the thickness of the thick-film section is gradually increased toward an edge of the gate insulating film.

(8) The semiconductor device according to (7), in which a top surface of the thick-film section is an inclined surface.

(9) The semiconductor device according to any one of (1) to (6), in which the thickness of the thick-film section is uniform.

(10) The semiconductor device according to any one of (1) to (9), in which the thick-film section has a laminate configuration.

(11) A semiconductor device including:

a gate electrode;

an oxide semiconductor film including a channel region facing the gate electrode; and

a gate insulating film provided between the gate electrode and the semiconductor film,

in which a low-dielectric constant section is provided in one or both of end portions of the gate insulating film, the low-dielectric constant section having a smaller dielectric constant than that of a portion other than the low-dielectric constant section of the gate insulating film.

(12) The semiconductor device according to (11), in which the low-dielectric constant section is formed of air.

(13) The semiconductor device according to (11), in which the low-dielectric constant section is formed of a low-dielectric constant material other than air.

(14) The semiconductor device according to (13), in which

a low-dielectric constant film is included, the low-dielectric constant film covering one or both of the end portions of the gate insulating film, and

the low-electric constant section is configured of a part of the low-dielectric constant film.

(15) The semiconductor device according to any one of (11) to (14), further including a source electrode and a drain electrode configured to be electrically connected to the oxide semiconductor film,

in which the low-dielectric constant section is provided in an end portion close to the drain electrode of the gate insulating film.

(16) The semiconductor device according to (15), in which the low-dielectric constant section is further provided in an end portion close to the source electrode of the gate insulating film as well.

(17) A display unit provided with a display device and a semiconductor device, the semiconductor device configured to drive the display device, the semiconductor device including:

an oxide semiconductor film;

a gate insulating film; and

a gate electrode,

the oxide semiconductor film, the gate insulating film, and the gate electrode being provided in this order on a substrate,

in which a thick-film section is provided in one or both of end portions of the gate insulating film, the thick-film section having a larger thickness than a thickness of a portion other than the thick-film section of the gate insulating film.

(18) A display unit provided with a display device and a semiconductor device, the semiconductor device configured to drive the display device, the semiconductor device including:

a gate electrode;

an oxide semiconductor film including a channel region facing the gate electrode; and

a gate insulating film provided between the gate electrode and the semiconductor film,

in which a low-dielectric constant section is provided in one or both of end portions of the gate insulating film, the low-dielectric constant section having a smaller dielectric constant than that of a portion other than the low-dielectric constant section of the gate insulating film.

(19) An electronic apparatus provided with a display unit, the display unit including a display device and a semiconductor device, the semiconductor device configured to drive the display device, the semiconductor device including:

an oxide semiconductor film;

a gate insulating film; and

a gate electrode,

the oxide semiconductor film, the gate insulating film, and the gate electrode being provided in this order on a substrate,

in which a thick-film section is provided in one or both of end portions of the gate insulating film, the thick-film section having a larger thickness than a thickness of a portion other than the thick-film section of the gate insulating film.

(20) An electronic apparatus provided with a display unit, the display unit including a display device and a semiconductor device, the semiconductor device configured to drive the display device, the semiconductor device including:

a gate electrode;

an oxide semiconductor film including a channel region facing the gate electrode; and

a gate insulating film provided between the gate electrode and the semiconductor film,

in which a low-dielectric constant section is provided in one or both of end portions of the gate insulating film, the low-dielectric constant section having a smaller dielectric constant than that of a portion other than the low-dielectric constant section of the gate insulating film.

It should be understood by those skilled in the art that various modifications, combinations, sub-combinations, and alterations may occur depending on design requirements and other factors insofar as they are within the scope of the appended claims or the equivalents thereof.

What is claimed is:

1. A semiconductor device comprising:
an oxide semiconductor film;
a gate insulating film; and
a gate electrode,
the oxide semiconductor film, the gate insulating film, and the gate electrode being provided in this order on a substrate,
wherein a thick-film section is provided in one or both of end portions of the gate insulating film, the thick-film section having a larger thickness than a thickness of a portion other than the thick-film section of the gate insulating film.

2. The semiconductor device according to claim 1, further comprising a source electrode and a drain electrode configured to be electrically connected to the oxide semiconductor film,
wherein the thick-film section is provided in an end portion close to the drain electrode of the gate insulating film.

3. The semiconductor device according to claim 2, wherein the oxide semiconductor film includes a channel region and a low-resistance region provided in a portion other than the channel region, the channel region being disposed at a position overlapping the gate electrode in a plan view.

4. The semiconductor device according to claim 3, wherein the source electrode and the drain electrode are electrically connected to the low-resistance region of the oxide semiconductor film.

5. The semiconductor device according to claim 3, further comprising a high-resistance film disposed in contact with the low-resistance region.

6. The semiconductor device according to claim 2, wherein the thick-film section is further provided in an end portion close to the source electrode of the gate insulating film.

7. The semiconductor device according to claim 1, wherein the thickness of the thick-film section is gradually increased toward an edge of the gate insulating film.

8. The semiconductor device according to claim 7, wherein a top surface of the thick-film section is an inclined surface.

9. The semiconductor device according to claim 1, wherein the thickness of the thick-film section is uniform.

10. The semiconductor device according to claim 1, wherein the thick-film section has a laminate configuration.

11. A semiconductor device comprising:
a gate electrode;
an oxide semiconductor film including a channel region facing the gate electrode; and
a gate insulating film provided between the gate electrode and the semiconductor film,
wherein a low-dielectric constant section is provided in one or both of end portions of the gate insulating film, the low-dielectric constant section having a smaller dielectric constant than that of a portion other than the low-dielectric constant section of the gate insulating film.

12. The semiconductor device according to claim 11, wherein the low-dielectric constant section is formed of air.

13. The semiconductor device according to claim 11, wherein the low-dielectric constant section is formed of a low-dielectric constant material other than air.

14. The semiconductor device according to claim 13, wherein
a low-dielectric constant film is included, the low-dielectric constant film covering one or both of the end portions of the gate insulating film, and
the low-electric constant section is configured of a part of the low-dielectric constant film.

15. The semiconductor device according to claim 11, further comprising a source electrode and a drain electrode configured to be electrically connected to the oxide semiconductor film,
wherein the low-dielectric constant section is provided in an end portion close to the drain electrode of the gate insulating film.

16. The semiconductor device according to claim 15, wherein the low-dielectric constant section is further provided in an end portion close to the source electrode of the gate insulating film as well.

17. A display unit provided with a display device and a semiconductor device, the semiconductor device configured to drive the display device, the semiconductor device comprising:
an oxide semiconductor film;
a gate insulating film; and
a gate electrode,
the oxide semiconductor film, the gate insulating film, and the gate electrode being provided in this order on a substrate,
wherein a thick-film section is provided in one or both of end portions of the gate insulating film, the thick-film section having a larger thickness than a thickness of a portion other than the thick-film section of the gate insulating film.

18. A display unit provided with a display device and a semiconductor device, the semiconductor device configured to drive the display device, the semiconductor device comprising:
a gate electrode;
an oxide semiconductor film including a channel region facing the gate electrode; and
a gate insulating film provided between the gate electrode and the semiconductor film,
wherein a low-dielectric constant section is provided in one or both of end portions of the gate insulating film, the low-dielectric constant section having a smaller dielectric constant than that of a portion other than the low-dielectric constant section of the gate insulating film.

19. An electronic apparatus provided with a display unit, the display unit including a display device and a semiconductor device, the semiconductor device configured to drive the display device, the semiconductor device comprising:
an oxide semiconductor film;
a gate insulating film; and
a gate electrode,
the oxide semiconductor film, the gate insulating film, and the gate electrode being provided in this order on a substrate,
wherein a thick-film section is provided in one or both of end portions of the gate insulating film, the thick-film section having a larger thickness than a thickness of a portion other than the thick-film section of the gate insulating film.

20. An electronic apparatus provided with a display unit, the display unit including a display device and a semiconductor device, the semiconductor device configured to drive the display device, the semiconductor device comprising:
a gate electrode;
an oxide semiconductor film including a channel region facing the gate electrode; and
a gate insulating film provided between the gate electrode and the semiconductor film,
wherein a low-dielectric constant section is provided in one or both of end portions of the gate insulating film, the low-dielectric constant section having a smaller dielectric constant than that of a portion other than the low-dielectric constant section of the gate insulating film.
